(19) United States
(12) Patent Application Publication
(10) Pub. No.: US 2025/0063729 A1
(43) Pub. Date: Feb. 20, 2025

(54) SEMICONDUCTOR DEVICES AND DATA STORAGE SYSTEMS INCLUDING THE SAME

(71) Applicant: SAMSUNG ELECTRONICS CO., LTD., Suwon-si (KR)

(72) Inventors: Junhyoung Kim, Suwon-si (KR); Joonyoung Kwon, Suwon-si (KR); Siwan Kim, Suwon-si (KR); Jiyoung Kim, Suwon-si (KR); Sukkang Sung, Suwon-si (KR)

(21) Appl. No.: 18/666,514

(22) Filed: May 16, 2024

(30) Foreign Application Priority Data
Jul. 7, 2023 (KR) 10-2023-0088413

(51) Int. Cl. H10B 41/35; H01L 23/00; H01L 25/18; H10B 12/00; H10B 41/41; H10B 43/35; H10B 43/40; H10B 80/00

(52) U.S. Cl. CPC H10B 41/35; H01L 25/18; H10B 12/50; H10B 41/41; H10B 43/35; H10B 43/40; H10B 80/00; H01L 24/08; H01L 2224/08145; H01L 2924/1431; H01L 2924/1436; H01L 2924/1438

(57) ABSTRACT

A semiconductor device includes a plate layer; conductive layers spaced apart from each other in a first direction perpendicular to an upper surface of the plate layer on the plate layer, extending by different lengths in a second direction perpendicular to the first direction, and forming a staircase region; a gap-fill insulating layer on the staircase region; and vertical structures penetrating through the gap-fill insulating layer and the conductive layers in the staircase region and extending in the first direction, and wherein the gap-fill insulating layer includes voids disposed symmetrically with respect to at least one of the vertical structures or a center of the staircase region in a third direction perpendicular to the first direction and the second direction.

### CROSS-REFERENCE TO RELATED APPLICATION(S)

This application claims benefit of priority to Korean Patent Application No. 10-2023-0088413, filed on Jul. 7, 2023, in the Korean Intellectual Property Office, the disclosure of which is incorporated herein by reference in its entirety.

### BACKGROUND

There has been a growing demand for high-capacity semiconductor data storage devices in data storage systems. Accordingly, a method for increasing data storage capacity of a semiconductor device has been researched. For example, as a method for increasing data storage capacity of a semiconductor device, a semiconductor device including memory cells disposed three-dimensionally, instead of memory cells disposed two-dimensionally, has been suggested.

### SUMMARY

The subject matter of the present disclosure generally relates to a semiconductor device having improved reliability and mass productivity and a data storage system including a semiconductor device having improved reliability and mass productivity.

According to some implementations of the present disclosure, a semiconductor device includes a first semiconductor structure including a substrate, circuit devices on the substrate, and circuit interconnection lines on the circuit devices; and a second semiconductor structure on the first semiconductor structure, wherein the second semiconductor structure includes a plate layer; gate electrodes spaced apart from each other in a first direction perpendicular to an upper surface of the plate layer on the plate layer, extending by different lengths in a second direction perpendicular to the first direction and forming staircase regions; a gap-fill insulating layer filling a region between the gate electrodes spaced apart from each other in a horizontal direction in the staircase regions; channel structures penetrating through at least a portion of the gate electrodes and extending in the first direction; and contact plugs penetrating through the gap-fill insulating layer and the gate electrodes in the staircase regions and extending in the first direction, wherein the gap-fill insulating layer extends along side surfaces of the gate electrodes and side surfaces of the contact plugs, and includes voids spaced apart from the contact plugs and the gate electrodes.

According to some implementations of the present disclosure, a semiconductor device includes a plate layer; conductive layers spaced apart from each other in a first direction perpendicular to an upper surface of the plate layer on the plate layer, extending by different lengths in a second direction perpendicular to the first direction, and forming a staircase region; a gap-fill insulating layer on the staircase region; and vertical structures penetrating through the gap-fill insulating layer and the conductive layers in the staircase region and extending in the first direction, and wherein the gap-fill insulating layer includes voids disposed symmetrically with respect to at least one of the vertical structures or a center of the staircase region in a third direction perpendicular to the first direction and the second direction.

According to some implementations of the present disclosure, a data storage system includes a semiconductor storage device including a first semiconductor structure including circuit devices, a second semiconductor structure on one surface of the first semiconductor structure, and an input/output pad electrically connected to the circuit devices; and a controller electrically connected to the semiconductor storage device through the input/output pad and configured to control the semiconductor storage device, wherein the second semiconductor structure includes a plate layer; gate electrodes spaced apart from each other in a first direction perpendicular to an upper surface of the plate layer on the plate layer, extending by different lengths in a second direction perpendicular to the first direction, and forming a staircase region; a gap-fill insulating layer on the staircase region; and contact plugs penetrating through the gap-fill insulating layer and the staircase region and extending in the first direction, and wherein the gap-fill insulating layer includes voids spaced apart from the contact plugs and the gate electrodes therein.

According to some implementations of the present disclosure, a method of manufacturing a semiconductor device includes forming a mold structure by alternately stacking sacrificial insulating layers and interlayer insulating layers on a plate layer; forming a staircase region having a step structure by partially removing the mold structure; forming a gap-fill sacrificial layer filling the staircase region; forming vertical sacrificial layers penetrating through the gap-fill sacrificial layer and the mold structure; removing the gap-fill sacrificial layer; and forming a gap-fill insulating layer including voids therein in a region from which the gap-fill sacrificial layer is removed.

### BRIEF DESCRIPTION OF DRAWINGS

The above and other aspects, features, and advantages of the present disclosure will be more clearly understood from the following detailed description, taken in combination with the accompanying drawings, in which:

FIG. 1 is a plan view illustrating a semiconductor device according to some implementations of the present disclosure;

FIGS. 2A and 2B are cross-sectional views illustrating a semiconductor device according to some implementations of the present disclosure;

FIGS. 3A to 3B are enlarged views illustrating a portion of a semiconductor device according to some implementations of the present disclosure;

FIGS. 4A to 4B are enlarged views illustrating a portion of a semiconductor device according to some implementations of the present disclosure;

FIGS. 5A and 5B are cross-sectional views illustrating a semiconductor device according to some implementations of the present disclosure;

FIGS. 6A and 6B are a plan view and a cross-sectional view, respectively, illustrating a semiconductor device according to some implementations of the present disclosure;

FIG. 7 is a cross-sectional view illustrating a semiconductor device according to some implementations of the present disclosure;

FIG. 8 is a cross-sectional view illustrating a semiconductor device according to some implementations of the present disclosure;

FIG. 9 is a cross-sectional view illustrating a semiconductor device according to some implementations of the present disclosure;

FIGS. 10A and 10B are cross-sectional views illustrating a semiconductor device according to some implementations of the present disclosure;

FIG. 11 is a cross-sectional view illustrating a semiconductor device according to some implementations of the present disclosure;

FIG. 12 is a flowchart illustrating a method of manufacturing a semiconductor device according to some implementations of the present disclosure;

FIGS. 13A to 13O are cross-sectional views illustrating a method of manufacturing a semiconductor device according to some implementations of the present disclosure;

FIG. 14 is a view illustrating a data storage system including a semiconductor device according to some implementations of the present disclosure;

FIG. 15 is a perspective view illustrating a data storage system including a semiconductor device according to some implementations of the present disclosure; and

FIG. 16 is a cross-sectional view illustrating a semiconductor package according to some implementations of the present disclosure.

### DETAILED DESCRIPTION

Hereinafter, implementations of the present disclosure will be described as follows with reference to the accompanying drawings.

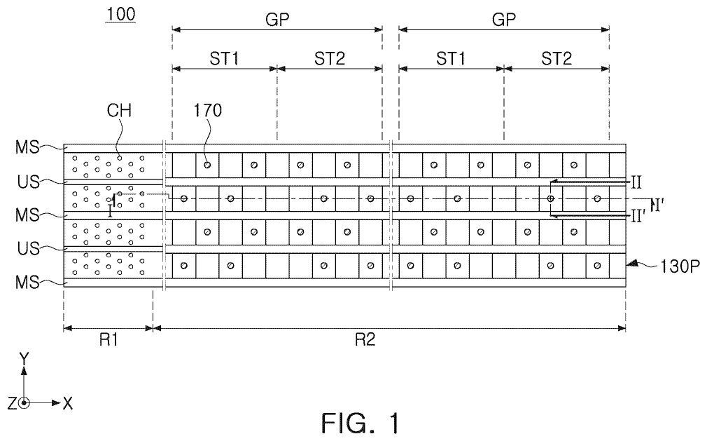

FIG. 1 is a plan view illustrating a semiconductor device according to some implementations.

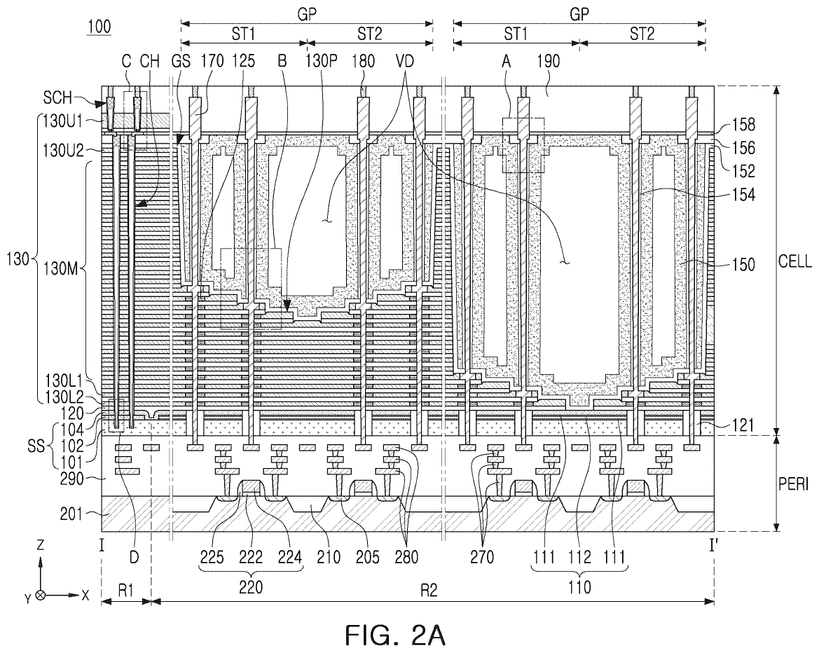

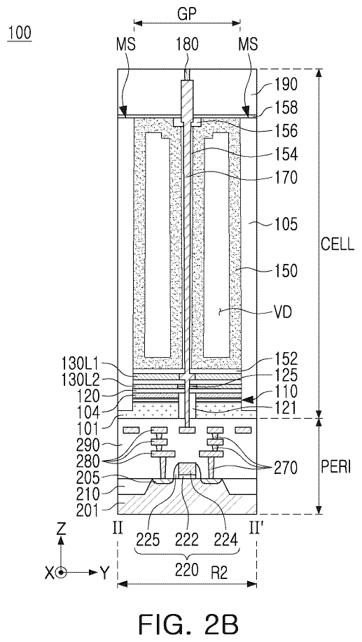

FIGS. 2A and 2B are cross-sectional views illustrating a semiconductor device according to some implementations, taken along lines I-I′ and II-II′, respectively, in FIG. 1.

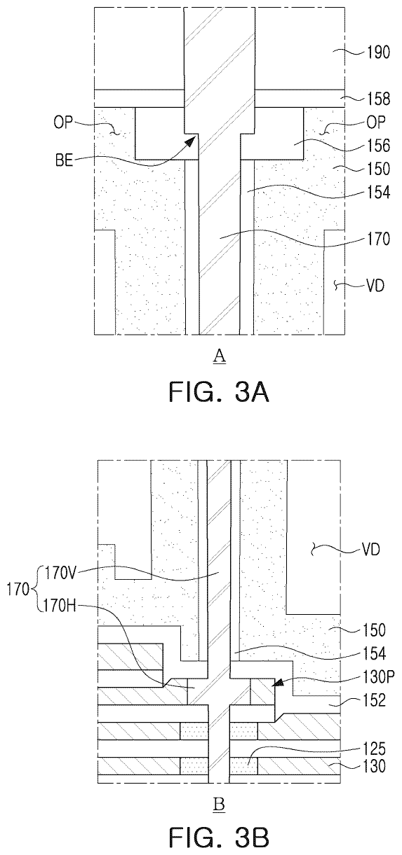

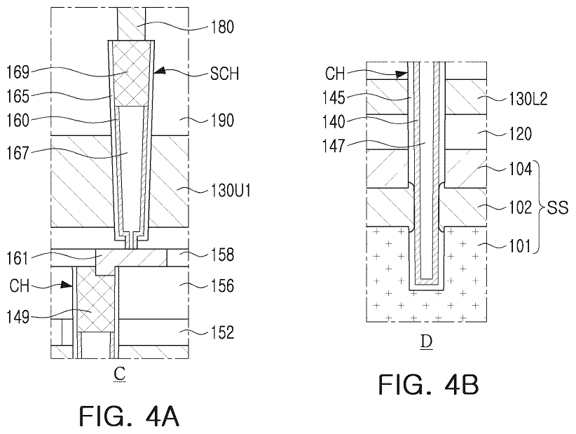

FIGS. 3A to 4B are enlarged views illustrating a portion of a semiconductor device according to some implementations. FIG. 3A is an enlarged view illustrating region “A” in FIG. 2A, FIG. 3B is an enlarged view illustrating region “B” in FIG. 2A, FIG. 4A is an enlarged view illustrating region “C” in FIG. 2A, and FIG. 4B is an enlarged view illustrating region “D” in FIG. 2A.

Referring to FIGS. 1 to 4B, a semiconductor device 100 includes a peripheral circuit region PERI, which is a first semiconductor structure including a substrate 201, and a memory cell region CELL, which is a second semiconductor structure including a plate layer 101. The memory cell region CELL may be disposed on the peripheral circuit region PERI. In some implementations, conversely, the memory cell region CELL may be disposed below the peripheral circuit region PERI.

Peripheral circuit region PERI includes a substrate 201, impurity regions 205 and device isolation layers 210 in the substrate 201, circuit devices 220 disposed on the substrate 201, a peripheral region insulating layer 290, circuit contact plugs 270, and circuit interconnection lines 280.

The substrate 201 may have an upper surface extending in the X-direction and the Y-direction. In the substrate 201, an active region may be defined by the device isolation layers 210. The impurity regions 205 including impurities may be disposed in a portion of the active region. The substrate 201 may include a semiconductor material, such as a group IV semiconductor, a group III-V compound semiconductor, or a group II-VI compound semiconductor. The substrate 201 may be provided as a bulk wafer or an epitaxial layer.

The circuit devices 220 may include planar transistors. Each of the circuit devices 220 includes a circuit gate dielectric layer 222, a spacer layer 224 and a circuit gate electrode 225. The impurity regions 205 may be disposed as source/drain regions in the substrate 201 on both sides of the circuit gate electrode 225.

The peripheral region insulating layer 290 may be disposed on the circuit devices 220 on the substrate 201. The peripheral region insulating layer 290 may include a plurality of insulating layers formed in different processes. The peripheral region insulating layer 290 may be formed of an insulating material.

The circuit contact plugs 270 and the circuit interconnection lines 280 may form a circuit interconnection structure electrically connected to the circuit devices 220 and the impurity regions 205. The circuit contact plugs 270 may have a cylindrical shape, and the circuit interconnection lines 280 may have a line shape. An electrical signal may be applied to the circuit devices 220 by the circuit contact plugs 270 and the circuit interconnection lines 280. In a region not illustrated, the circuit contact plugs 270 may also be connected to the circuit gate electrode 225. The circuit interconnection lines 280 may be connected to the circuit contact plugs 270, may have a line shape, and may be disposed in a plurality of layers. The circuit contact plugs 270 and the circuit interconnection lines 280 may include a conductive material, for example, tungsten (W), copper (Cu), aluminum (Al), and the like, and each component may further include a diffusion barrier. In some implementations, the number of layers of the circuit contact plugs 270 and the number of layers of the circuit interconnection lines 280 may be varied.

The memory cell region CELL has first and second regions R1 and R2, and includes a source structure SS, gate electrodes 130 stacked on the source structure SS and forming the staircase regions GP in the second region R2, interlayer insulating layers 120 alternately stacked with the gate electrodes 130, first channel structures CH and second channel structures SCH disposed to penetrate through a stack structure GS of the gate electrodes 130 in the first region R1, first isolation regions MS extending by penetrating through the gate electrodes 130, second isolation regions US penetrating through a portion of the gate electrodes 130 disposed on an upper portion, a gap-fill insulating layer 150 covering an end of gate electrodes 130 and filling the staircase regions GP, contact plugs 170 connected to the gate electrodes 130 and extending vertically in the second region R2.

The memory cell region CELL includes a horizontal sacrificial layer 110 disposed below the gate electrodes 130 in the second region R2, substrate insulating layers 121 disposed to penetrate through the plate layer 101, side-surface insulating layers disposed around the contact plugs 170, a first cell insulating layer 152 covering the stack structure GS of the gate electrodes 130, a second cell insulating layer 154 covering side surfaces of the contact plugs 170, a third cell insulating layer 156 on the gap-fill insulating layer 150, a horizontal insulating layer 158 on the third cell insulating layer 156, an upper insulating layer 190 on the horizontal insulating layer 158, and studs 180 on the second channel structures SCH and the contact plugs 170.

In the memory cell region CELL, in the first region R1, the gate electrodes 130 may be vertically stacked and the first channel structures CH may be disposed, and memory cells may be disposed in the first region R1. In the second region R2, the gate electrodes 130 may extend to different lengths and may form staircase regions GP, and the second region R2 may be configured to electrically connect the memory cells to the peripheral circuit region PERI. The second region R2 may be disposed on at least one end of the first region R1 in at least one direction, for example, the X-direction.

The source structure SS includes a plate layer 101, a first horizontal conductive layer 102, and a second horizontal conductive layer 104 stacked in order in the first region R1. However, in some implementations, the number of conductive layers included in the source structure SS may be varied.

The plate layer 101 may have a plate shape and may function as at least a portion of a common source line of the semiconductor device 100. The plate layer 101 may have an upper surface extending in the X-direction and the Y-direction. The plate layer 101 may include a conductive material. For example, the plate layer 101 may include a semiconductor material, such as a group IV semiconductor, a group III-V compound semiconductor, or a group II-VI compound semiconductor. For example, the group IV semiconductor may include silicon, germanium, or silicon-germanium. The plate layer 101 may further include impurities. The plate layer 101 may be provided as a polycrystalline semiconductor layer such as a polycrystalline silicon layer or an epitaxial layer.

The first and second horizontal conductive layers 102 and 104 may be stacked in order on an upper surface of the plate layer 101 in the first region R1. The first horizontal conductive layer 102 may not extend to the second region R2, and the second horizontal conductive layer 104 may extend to the second region R2. The first horizontal conductive layer 102 may function as a portion of a common source line of the semiconductor device 100, and may function as a common source line together with the plate layer 101, for example. As illustrated in FIG. 4B, the first horizontal conductive layer 102 may be directly connected to the channel layer 140 around the channel layer 140.

The first and second horizontal conductive layers 102 and 104 may include a semiconductor material, such as polycrystalline silicon. In this case, at least the first horizontal conductive layer 102 may be a layer doped with impurities having the same conductivity as that of the plate layer 101, and the second horizontal conductive layer 104 may be a doped layer or a layer including impurities diffused from the first horizontal conductive layer 102.

The horizontal sacrificial layer 110 may be disposed on the plate layer 101 on the same level as a level of the first horizontal conductive layer 102 in at least a portion of the second region R2. The horizontal sacrificial layer 110 includes first and second horizontal sacrificial layers 111 and 112 alternately stacked on the second region R2 of the plate layer 101. The horizontal sacrificial layer 110 may be layers remaining after a portion thereof are replaced with the first horizontal conductive layer 102 during a manufacturing process.

The horizontal sacrificial layer 110 may include silicon oxide, silicon nitride, silicon carbide, or silicon oxynitride. The first horizontal sacrificial layers 111 and the second horizontal sacrificial layer 112 may include different insulating materials. For example, the first horizontal sacrificial layers 111 may be formed of the same material as that of the interlayer insulating layers 120, and the second horizontal sacrificial layer 112 may be formed of a material different from that of the interlayer insulating layers 120.

The substrate insulating layers 121 may be disposed to penetrate through the plate layer 101, the horizontal sacrificial layer 110, and the second horizontal conductive layer 104 in a portion of the second region R2. The substrate insulating layers 121 may be further disposed in the first region R1 and, for example, may be disposed in a region in which a through-via extending from the memory cell region CELL to the peripheral circuit region PERI are disposed. An upper surface of the substrate insulating layer 121 may be coplanar with an upper surface of the second horizontal conductive layer 104. The substrate insulating layer 121 may include an insulating material such as silicon oxide, silicon nitride, silicon carbide, or silicon oxynitride.

The gate electrodes 130 may be vertically stacked and spaced apart from each other on the plate layer 101, and a portion thereof may form a stack structure GS together with the interlayer insulating layers 120. The gate electrodes 130 includes a first upper gate electrode 130U1 included in string selection transistors, a second upper gate electrode 130U2 included in an erase transistor, memory gate electrodes 130M included in a plurality of memory cells, first lower gate electrode 130L1 included in an erase transistor, and a second lower gate electrode 130L2 forming the ground selection transistor. The number of the memory gate electrodes 130M included in memory cells may be determined depending on capacity of the semiconductor device 100. The first upper gate electrode 130U1 and the second lower gate electrode 130L2 may also be referred to as an upper select gate electrode and a lower select gate electrode, respectively. In some implementations, each of the number of the first upper gate electrode 130U1, the number of the second upper gate electrode 130U2, the number of the first lower gate electrode 130L1, and the number of the second lower gate electrode 130L2 may be 1 to 4 or more. Each of the first upper gate electrode 130U1, the second upper gate electrode 130U2, the first lower gate electrode 130L1, and the second lower gate electrode 130L2 may have a structure the same as or different from that of the memory gate electrodes 130M.

In some implementations, positions of the first upper gate electrode 130U1 and the second upper gate electrode 130U2 may be interchanged, or positions of the first lower gate electrode 130L1 and the second lower gate electrode 130L2 may be interchanged. In some implementations, the second upper gate electrode 130U2 and/or the first lower gate electrode 130L1 may not be provided. In some implementations, a dummy gate electrode may be additionally disposed.

The gate electrodes 130 may be vertically stacked and spaced apart from each other on the first region R1, may extend to different lengths from the first region R1 to the second region R2 and may form step structures ST1 and ST2 of a staircase form in the staircase regions GP. However, the first upper gate electrode 130U1 may extend to a relatively short length and may not form the staircase region GP. As illustrated in FIG. 2A, the gate electrodes 130 may have a shape removed to a predetermined depth from an upper portion of the staircase regions GP, and the staircase regions GP may have different depths. The staircase regions GP may have a shape in which a depth thereof may increase in a direction away from the first region R1 in the X-direction, but implementations are not limited thereto. The gate electrodes 130 may form dummy structures between the staircase regions GP. The levels of the uppermost surfaces of the dummy structures may be the same, but implementations are not limited thereto. In some implementations, a level of uppermost surfaces of the dummy structures may decrease in a direction away from the first region R1 in the X-direction.

The gate electrodes 130 may form first and second step structures ST1 and ST2 in a symmetrical or asymmetrical form in the X-direction in each of the staircase regions GP. The first step structure ST1 may have a staircase structure relatively adjacent to the first region R1 and having a level decreasing in the X-direction. The second step structure ST2 may be a staircase structure disposed in a position spaced apart from the first region R1 and having a level increasing in the X-direction. For example, in each staircase regions GP, a slope of the first step structure ST1 may be equal to or smaller than a slope of the second step structure ST2.

In some implementations, the specific shape of the staircase regions GP and the specific shape of the first and second step structures ST1 and ST2, and the number of gate electrodes 130 included in each of the first and second step structures ST1 and ST2 are not limited to the example illustrated in FIG. 2A. In some implementations, the gate electrodes 130 may be disposed to have a step structure in the Y-direction.

With the first and second step structures ST1 and ST2, the gate electrodes 130 may have contact regions 130P, respectively, in which the lower gate electrode 130 may extend longer than the upper gate electrode 130, and may be exposed upwardly from the interlayer insulating layers 120. The gate electrodes 130 may be connected to contact plugs 170, respectively, in contact regions 130P, which are end regions. The gate electrodes 130 excluding the first upper gate electrode 130U1 may have an increased thickness in the contact regions 130P.

The gate electrodes 130 may include a metal material, such as tungsten (W), or may include polycrystalline silicon or a metal silicide material. For example, the first upper gate electrode 130U1 may include polycrystalline silicon, and the other gate electrodes 130 may include a metal material. In some implementations, the gate electrodes 130 may further include a diffusion barrier, and for example, the diffusion barrier may include tungsten nitride (WN), tantalum nitride (TaN), titanium nitride (TiN), or a combination thereof.

The interlayer insulating layers 120 may be disposed between the gate electrodes 130 other than the first upper gate electrode 130U1. Similarly to the gate electrodes 130, the interlayer insulating layers 120 may be spaced apart from each other in a direction perpendicular to an upper surface of the plate layer 101 and may extend in the X-direction. The interlayer insulating layers 120 may include an insulating material such as silicon oxide or silicon nitride.

First channel structures CH may penetrate through the gate electrodes 130 other than the first upper gate electrode 130U1, may extend in the Z-direction, and may be connected to the plate layer 101. The first channel structures CH may form a memory cell string together with the second channel structures SCH, and may be spaced apart from each other while forming rows and columns on the plate layer 101 in the first region R1. The first channel structures CH may be disposed to form a lattice pattern on the X-Y plane or in a zigzag pattern in one direction. The first channel structures CH may have a columnar shape and may have an inclined side surface having a width decreasing toward the plate layer 101. At least a portion of the first channel structures CH, including the first channel structures CH disposed on an end of the first region R1, may be dummy channel structures.

As illustrated in FIGS. 4A and 4B, each of the first channel structures CH includes a first channel layer 140, a first gate dielectric layer 145, a first channel filling insulating layer 147, and a first channel pad 149 disposed in a lower channel hole. The first channel layer 140 may be formed in an annular shape surrounding the internal first channel filling insulating layer 147, or, in some implementations, the first channel layer 140 may have a columnar shape such as a cylindrical shape or a prism shape without the first channel filling insulating layer 147. The first channel layer 140 may be connected to the first horizontal conductive layer 102 in a lower portion. The first channel layer 140 may include a semiconductor material such as polycrystalline silicon or single crystalline silicon.

The first gate dielectric layer 145 may be disposed between the gate electrodes 130 and the first channel layer 140. Although not specifically illustrated, the first gate dielectric layer 145 may include a tunneling layer, a charge storage layer, and a blocking layer stacked in order from the first channel layer 140. The tunneling layer may tunnel electric charges into the charge storage layer, and may include, for example, silicon oxide (SiO₂), silicon nitride (Si₃N₄), silicon oxynitride (SiON), or a combination thereof. The charge storage layer may be a charge trap layer or a floating gate conductive layer. The blocking layer may include silicon oxide (SiO₂), silicon nitride (Si₃N₄), silicon oxynitride (SiON), a high-κ dielectric material, or a combination thereof. In some implementations, at least a portion of the first gate dielectric layer 145 may extend in a horizontal direction along the gate electrodes 130. The first channel pad 149 may be disposed on an upper end of the first channel structure CH. The first channel pad 149 may include, for example, doped polycrystalline silicon.

The second channel structures SCH may penetrate through the first upper gate electrode 130U1, may extend in the Z-direction, and may be connected to the first channel structures CH, respectively. The second channel structures SCH may be disposed on the first channel structures CH, respectively, and may be horizontally shifted from the first channel structures CH, but some implementations thereof is not limited thereto.

As illustrated in FIG. 4A, each of the second channel structure SCH includes a second channel layer 160, a connection pad 161, a second gate dielectric layer 165, a second channel filling insulating layer 167, and a second channel pad 169 disposed in an upper channel hole. The second channel layer 160 may be formed in an annular shape surrounding the second channel filling insulating layer 167 therein. The second channel layer 160 may be connected to the connection pad 161 in a lower portion and may be electrically connected to the first channel layer 140 of the first channel structure CH through the connection pad 161. The connection pad 161 may be disposed below the second channel layer 160 and may be partially recessed into the first channel pads 149. In some implementations, the connection pad 161 and the second channel layer 160 may be integrated with each other.

The description of materials of the first channel layer 140, the first gate dielectric layer 145, the first channel filling insulating layer 147, and the first channel pad 149 described above may be applied to a description of materials of the second channel layer 160, the second gate dielectric layer 165, the second channel filling insulating layer 167, and the second channel pad 169, respectively. The connection pad 161 may include a conductive material, for example polycrystalline silicon.

The first isolation regions MS may penetrate through at least a portion of the gate electrodes 130 and may extend in the X-direction. As illustrated in FIG. 1, the first isolation regions MS may be disposed in parallel to each other. As illustrated in FIG. 2B, the first isolation regions MS may penetrate through the gate electrodes 130 stacked on the plate layer 101, may further penetrate through the first and second horizontal conductive layers 102 and 104, and may be connected to the plate layer 101. The first isolation regions MS may be disposed to penetrate through the gate electrodes 130 other than the first upper gate electrode 130U1. A portion of the isolation regions MS may extend to as an integrated region along the first region R1 and the second region R2, and another portion may extend only to a portion of the second region R2 or may be intermittently disposed in the first region R1 and the second region R2. However, in some implementations, the arrangement form of the first isolation regions MS and the number of the first isolation regions MS are not limited to the illustrated examples in FIG. 1.

A gate isolation insulating layer 105 may be disposed in each of the first isolation regions MS. The gate isolation insulating layer 105 may have a shape of which a width may decrease toward the plate layer 101 due to a high aspect ratio. The gate isolation insulating layer 105 may include an insulating material, for example, silicon oxide, silicon nitride, or silicon oxynitride.

As illustrated in FIG. 1, the second isolation regions US may extend in the X-direction between first isolation regions MS adjacent to each other. The second isolation regions US may be disposed in a portion of the second region R2 and the first region R1. The second isolation regions US may penetrate through the first upper gate electrode 130U1 disposed in an uppermost portion of the gate electrodes 130. The second isolation regions US may divide the first upper gate electrode 130U1 in the Y-direction.

The gap-fill insulating layer 150 may cover ends of the gate electrodes 130 other than the first upper gate electrode 130U1 and may fill the staircase regions GP. The gap-fill insulating layer 150 may extend with a substantially constant thickness along the ends of the gate electrodes 130 and side surfaces of the contact plugs 170. The gap-fill insulating layer 150 may extend with a substantially constant thickness along the gate electrodes 130 and the contact plugs 170 in the staircase regions GP.

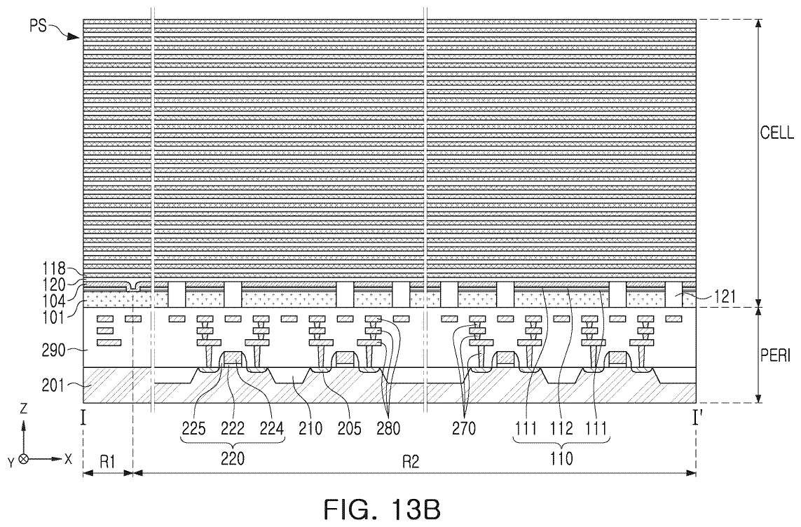

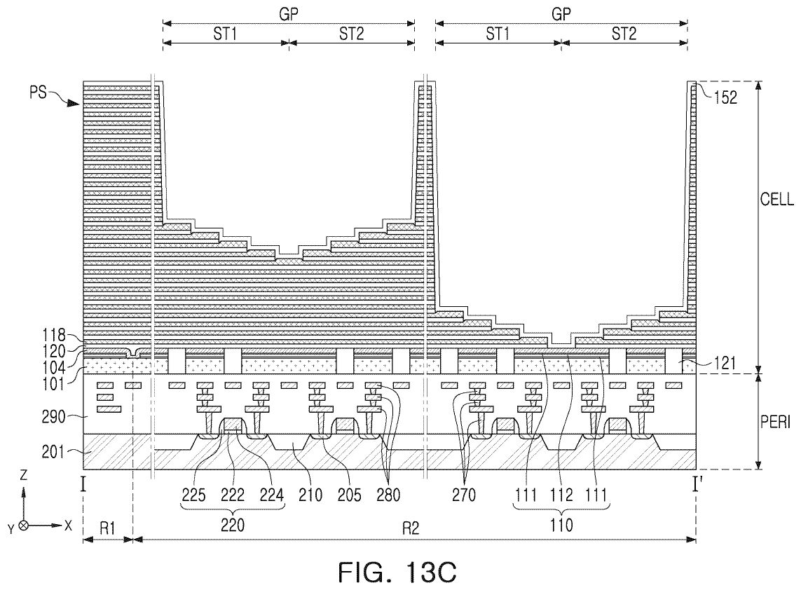

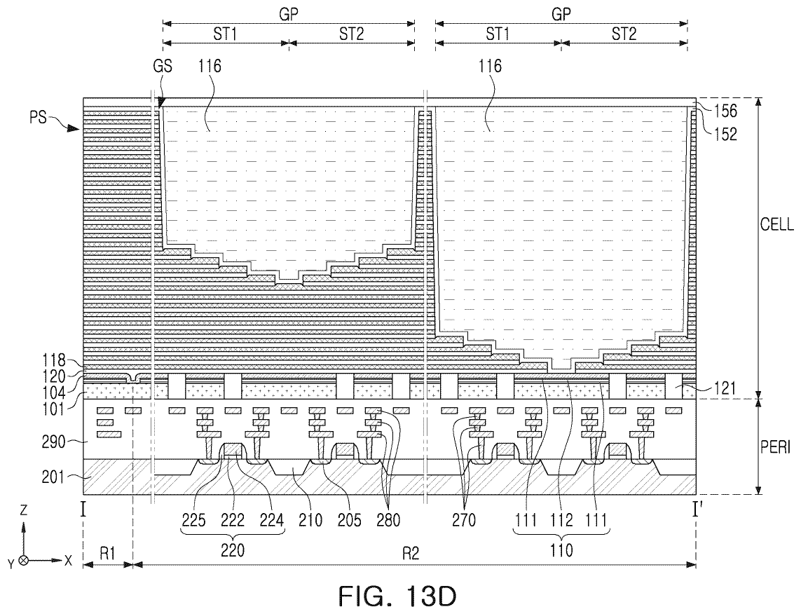

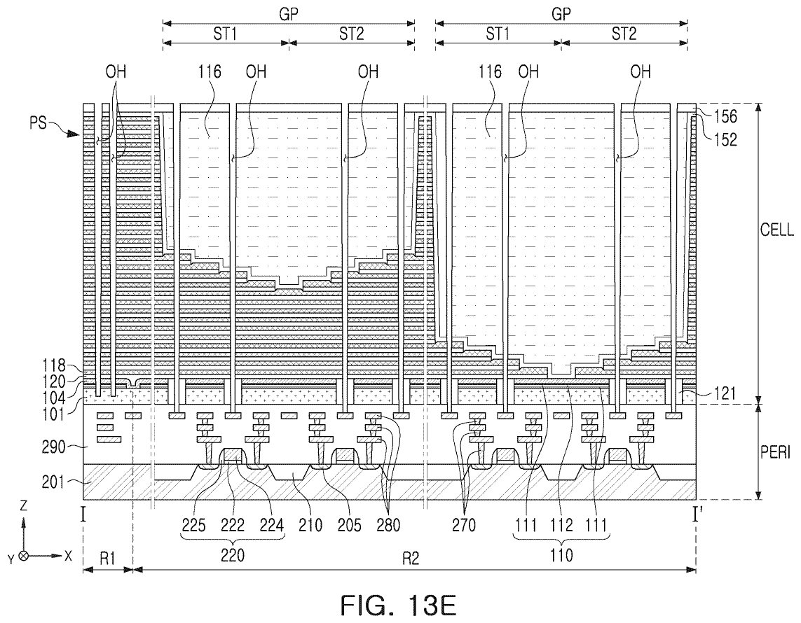

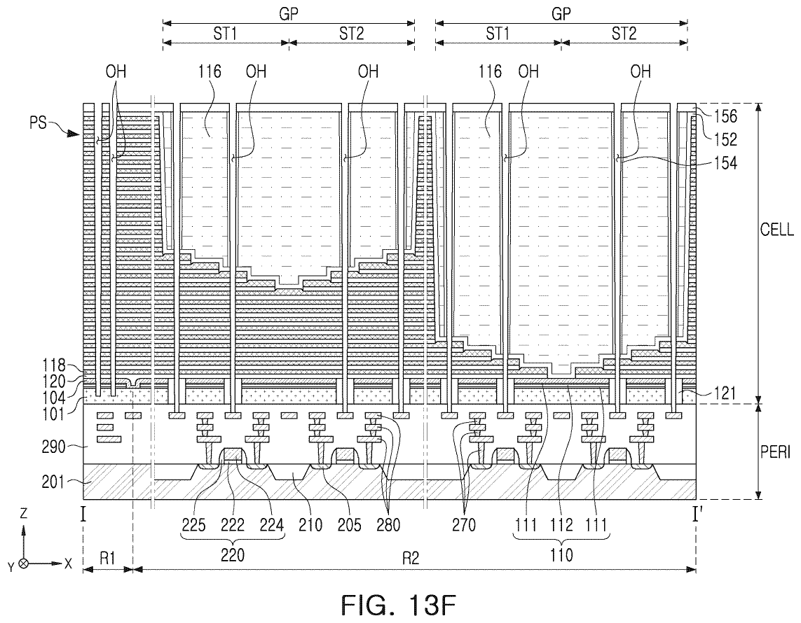

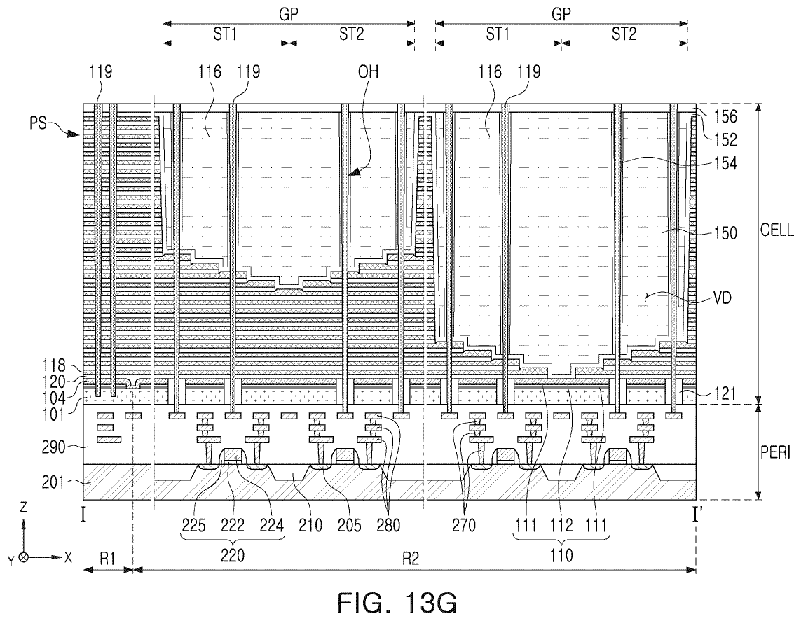

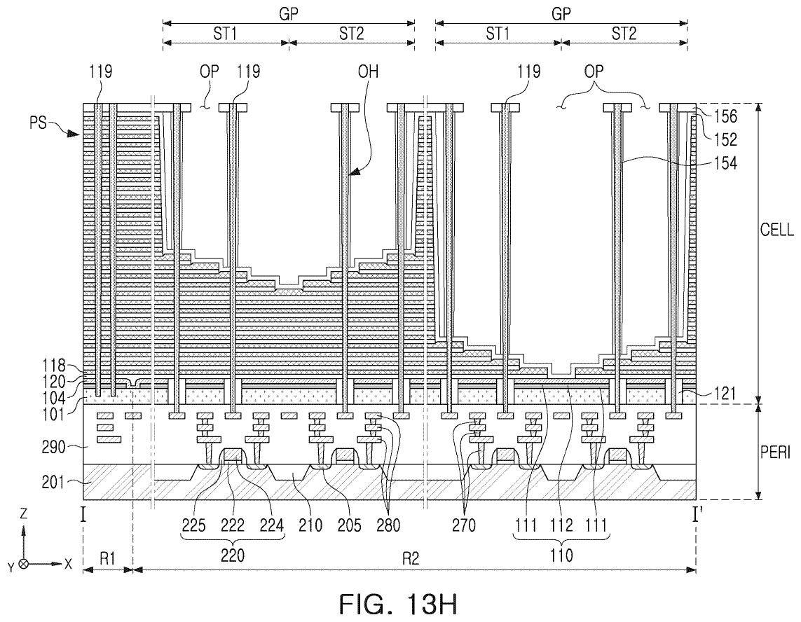

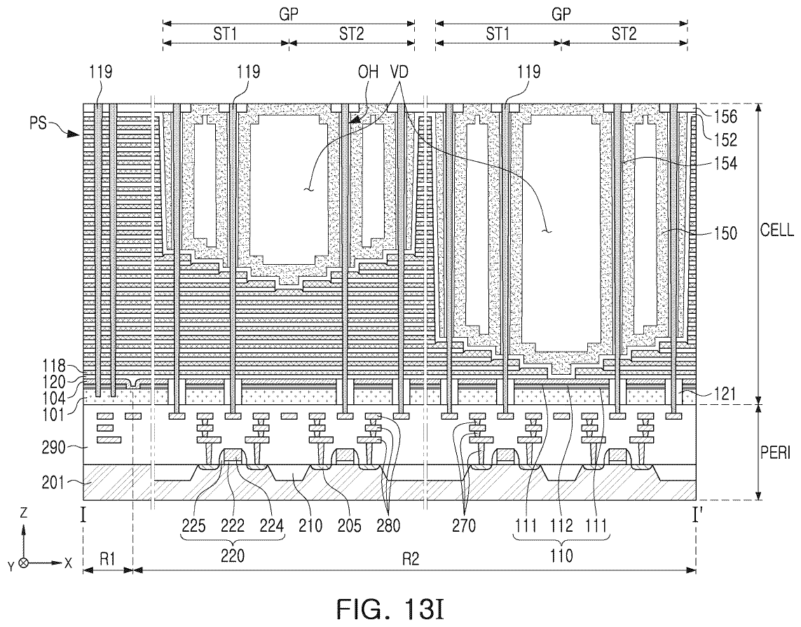

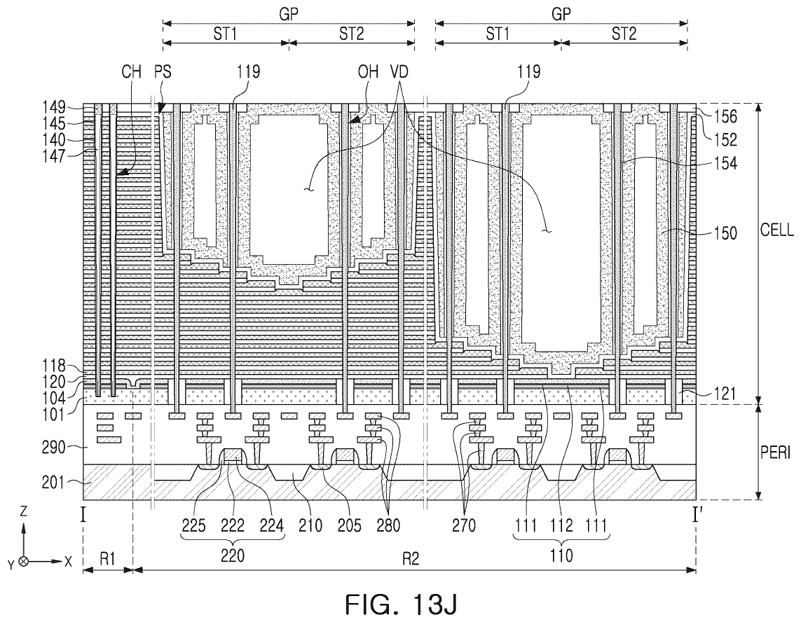

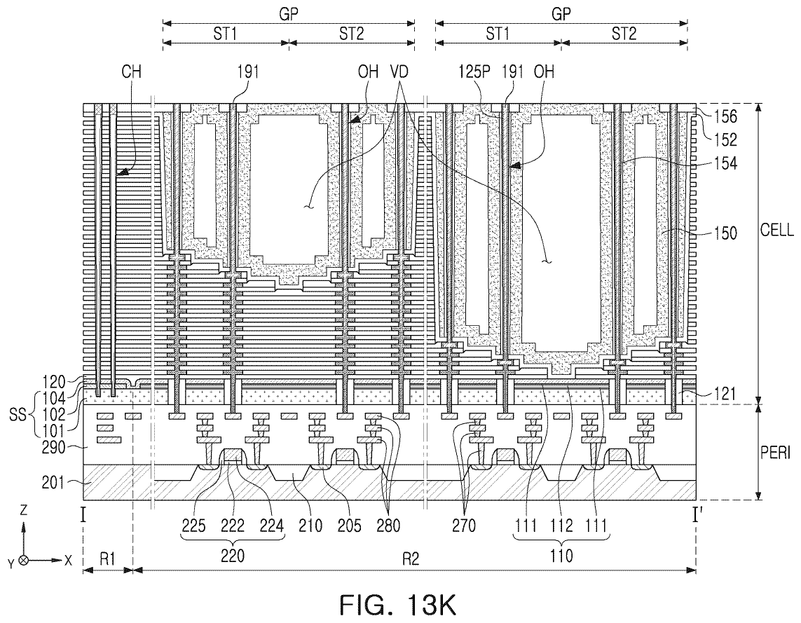

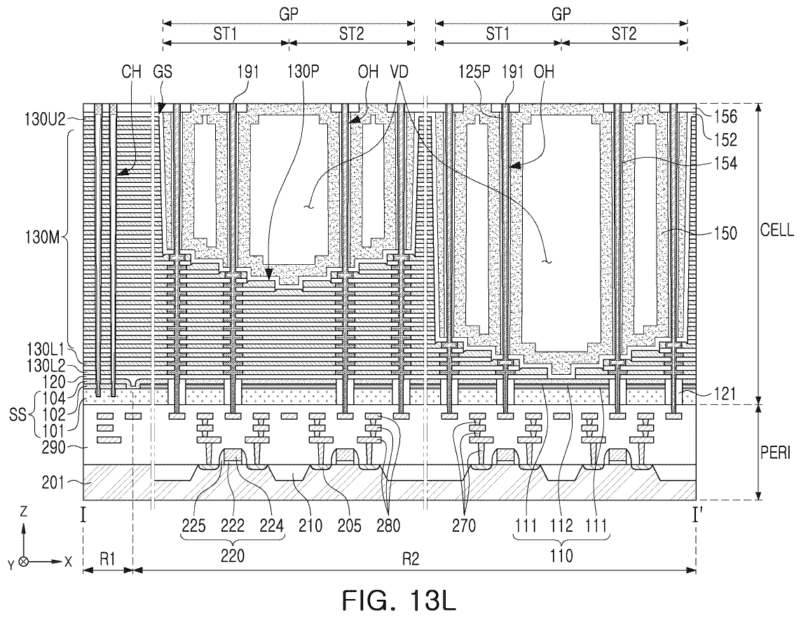

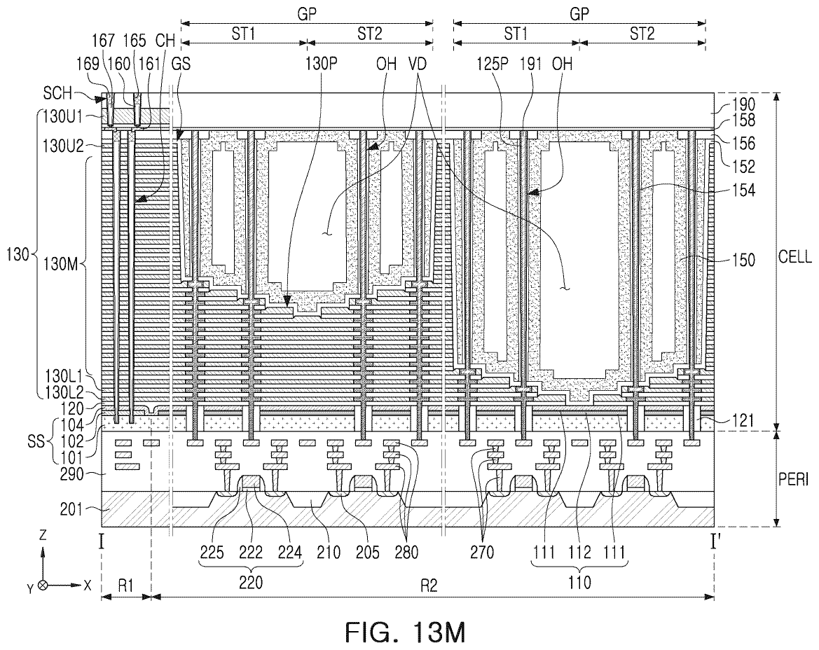

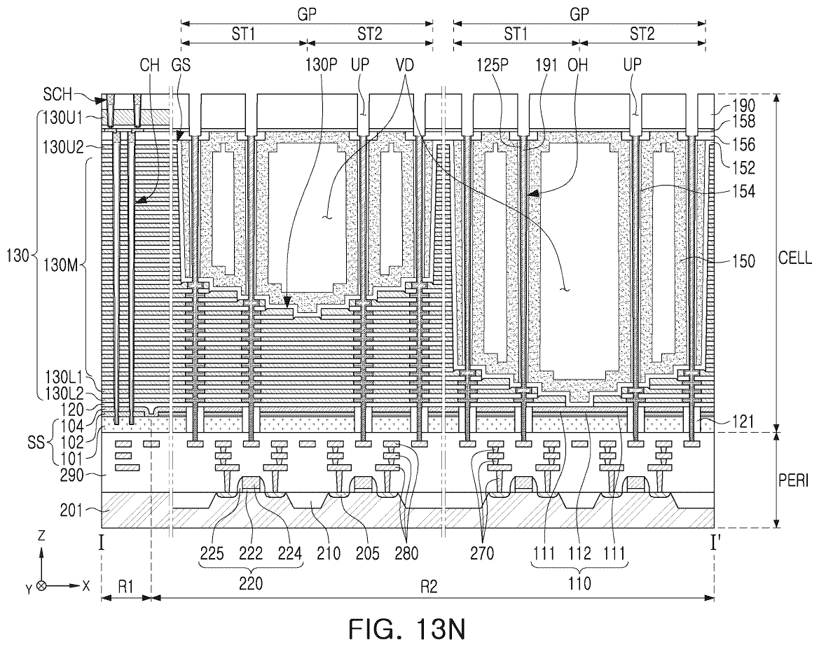

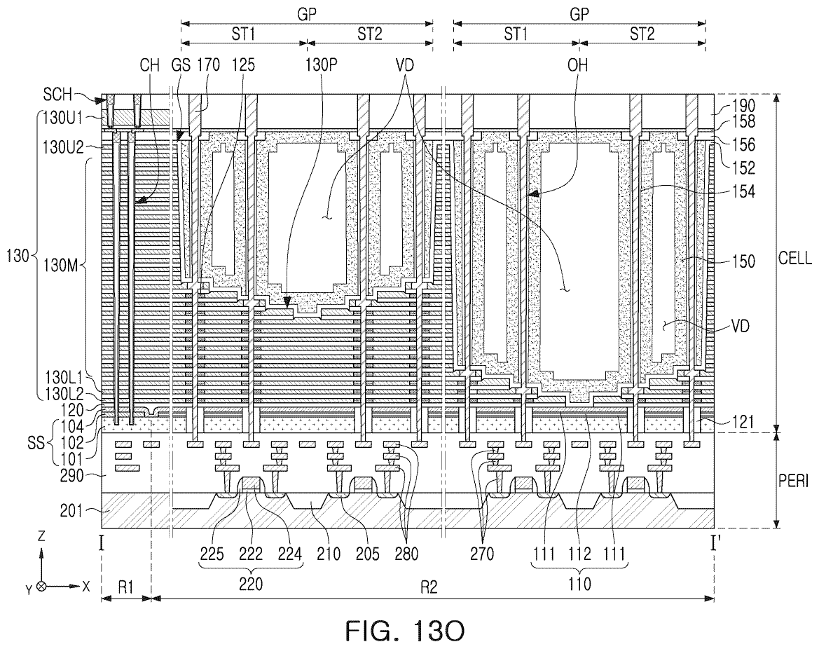

The gap-fill insulating layer 150 may have voids VD therein. The voids VD may include gas and may also be referred to as air gaps. The voids VD may be spaced apart from the stack structure GS and the contact plugs 170. The voids VD may be spaced apart from the gate electrodes 130. The voids VD may be disposed between the contact plugs 170 and between the contact plugs 170 and the stack structure GS. The voids VD may also be disposed between the contact plugs 170 and the first isolation regions MS. As illustrated in FIG. 2B, in a cross-section in the Y-direction, the voids VD may be symmetrically disposed on both sides of the contact plug 170 with the contact plug 170 as a center. The voids VD may be disposed symmetrically with respect to a center of the staircase region GP in the cross-section in the Y-direction. The gap-fill insulating layer 150 may be formed by replacing the gap-fill sacrificial layer 116 (see FIG. 13D), such that voids VD may be disposed therein, which will be described in greater detail with reference to FIGS. 13A to 13O below.

The voids VD may include lower regions having a staircase shape corresponding to a shape of the staircase regions GP. In the lower regions, the voids VD may have a staircase shape of the staircase regions GP or a shape in which the step structure thereof may be relaxed or alleviated while corresponding the staircase shape of the staircase regions GP. A thickness of the gap-fill insulating layer 150 surrounding the voids VD may be substantially constant, and the thickness may be varied in some implementations. Accordingly, a size of the voids VD may be varied. In some implementations, when a distance between the contact plugs 170 is relatively short or the thickness of the gap-fill insulating layer 150 is relatively large, the void VD may not be present between some of the contact plugs 170.

The first cell insulating layer 152 may be a cover insulating layer conformally covering the stack structure GS. The first cell insulating layer 152 may cover side surfaces of the gate electrodes 130 included in the stack structure GS and side surfaces of the interlayer insulating layers 120 and may cover an upper surface of the stack structure GS, for example, an upper surface of the second upper gate electrode 130U2. The first cell insulating layer 152 may be in contact with the gap-fill insulating layer 150.

The second cell insulating layers 154 may cover a portion of side surfaces of the contact plugs 170. Specifically, the second cell insulating layers 154 may be interposed between the side surfaces of the contact plugs 170 and the gap-fill insulating layer 150. The second cell insulating layers 154 may be disposed on the first cell insulating layer 152 and may be disposed below the third cell insulating layer 156 in the Z-direction. Internal side surfaces of the second cell insulating layers 154 may be in contact with the contact plugs 170, and external side surfaces of the second cell insulating layers 154 may be in contact with the gap-fill insulating layer 150. The second cell insulating layers 154 may be oxide layers formed by an oxidation process.

The third cell insulating layer 156 may be disposed on the gap-fill insulating layer 150 and the stack structure GS and may extend horizontally in the first region R1 and the second region R2. The third cell insulating layer 156 may support a mold structure including the interlayer insulating layers 120 during a manufacturing process. As illustrated in FIG. 3A, the third cell insulating layer 156 includes openings OP spaced apart from the contact plugs 170. The openings OP may be filled with the gap-fill insulating layer 150. In some implementations, the size of the openings OP and the arrangement form of the openings OP may be varied. In some implementations, the third cell insulating layer 156 may not be provided.

The first to third cell insulating layers 152, 154, and 156 may include an insulating material, and may include, for example, silicon oxide, silicon nitride, or silicon oxynitride.

The horizontal insulating layer 158 may be disposed between the first channel structures CH and the second channel structures SCH and may extend horizontally in the first region R1 and the second region R2. The horizontal insulating layer 158 may be disposed between the first upper gate electrode 130U1 and the second upper gate electrode 130U2. The horizontal insulating layer 158 may be used as an etch stop layer when forming the second channel structures SCH and may also be used when forming the connection pads 161.

The horizontal insulating layer 158 may include an insulating material and may include a material different from those of the gap-fill insulating layer 150, the third cell insulating layer 156, and the upper insulating layer 190. The horizontal insulating layer 158 may include nitride, and may include, for example, at least one of SiN, SiON, SiCN, and SiOCN.

The upper insulating layer 190 may be disposed to cover the contact plugs 170 on the horizontal insulating layer 158. The upper insulating layer 190 may be formed of an insulating material and may also include a plurality of insulating layers.

The contact plugs 170 may be connected to the contact regions 130P of the gate electrodes 130 disposed in an uppermost portion in the gate pad regions GP of the second region R2. The arrangement form of the contact plugs 170 on the plan view in FIG. 1 may be varied in some implementations. The contact plugs 170 may penetrate through at least a portion of the upper insulating layer 190 and the gap-fill insulating layer 150 and may be connected to the contact regions 130P of the gate electrodes 130 exposed upwardly, respectively. The contact plugs 170 may penetrate through the gate electrodes 130 below contact regions 130P, may penetrate through the second horizontal conductive layer 104, the horizontal sacrificial layer 110, and the plate layer 101 and may be connected to the circuit interconnection lines 280 in the peripheral circuit region PERI. The contact plugs 170 may be spaced apart from the gate electrodes 130 disposed below the contact regions 130P by side-surface insulating layers 125. The contact plugs 170 may be spaced apart from the plate layer 101, the horizontal sacrificial layer 110, and the second horizontal conductive layer 104 by the substrate insulating layers 121. However, in some implementations, the contact plugs 170 may be disposed to not penetrate through the gate electrodes 130. In this case, the contact plugs 170 may be connected to the contact regions 130P of the gate electrodes 130 exposed upwardly, respectively. In some implementations, each of the contact plugs 170 may further include a landing region of which a width may extend below the substrate insulating layer 121.

The contact plugs 170 may be spaced apart from the voids VD in the gap-fill insulating layer 150. The contact plugs 170 may penetrate through the gap-fill insulating layer 150 without penetrating through the voids VD or without being in contact with the voids VD. Accordingly, the contact plugs 170 may have a stable pillar shape without defects such as distortion and twisting.

As illustrated in FIG. 3A, each of the contact plugs 170 may have a bent portion BE of which a width may discontinuously change below the horizontal insulating layer 158. The bent portion BE may be disposed in the third cell insulating layer 156, and may be varied in the range of being disposed below the lower surface of the horizontal insulating layer 158. In some implementations, the contact plugs 170 may not have a bent portion BE.

As illustrated in FIG. 3B, each of the contact plugs 170 may have a horizontally extended form in the contact region 130P. The contact plug 170 includes a vertical extension 170V extending in the Z-direction and a horizontal extension 170H extending horizontally from the vertical extension 170V and in contact with the gate electrode 130. The horizontal extension 170H may be disposed along a circumference of the vertical extension 170V, and the entire side surface thereof may be surrounded by the gate electrode 130. A length from a side surface of the vertical extension 170V to an end of the horizontal extension 170H may be smaller than a length from a side surface of the vertical extension 170V to external side surfaces of the side-surface insulating layers 125. The contact plugs 170 may be spaced apart from the gate electrodes 130 disposed below the contact regions 130P, that is, gate electrodes 130 not electrically connected, by the side-surface insulating layers 125.

The contact plugs 170 may include at least one of a conductive material, for example, tungsten (W), copper (Cu), aluminum (Al), and an alloy thereof. In some implementations, the contact plugs 170 may include a barrier layer extending along a side surface and a bottom surface, or may have an air gap therein.

The side-surface insulating layers 125 may be disposed to surround the side surface of each of the contact plugs 170 below the contact regions 130P. The side-surface insulating layers 125 may be spaced apart from each other in the Z-direction around each of the contact plugs 170. The side-surface insulating layers 125 may be disposed on substantially the same level as a level of the gate electrodes 130. The side-surface insulating layers 125 may include an insulating material, for example, silicon oxide, silicon nitride, or silicon oxynitride.

The studs 180 may be included in a cell interconnection structure electrically connected to memory cells in the memory cell region CELL. The studs 180 may be connected to the second channel structures SCH and the contact plugs 170, and may be electrically connected to the first and second channel structures CH and SCH and the gate electrodes 130. The studs 180 may have a plug shape, but implementations are not limited thereto. In some implementations, the studs 180 may have a line shape. In some implementations, the number of plugs and the number of interconnection lines included in the cell interconnection structure may be varied. The studs 180 may include metal, for example, tungsten (W), copper (Cu), or aluminum (Al).

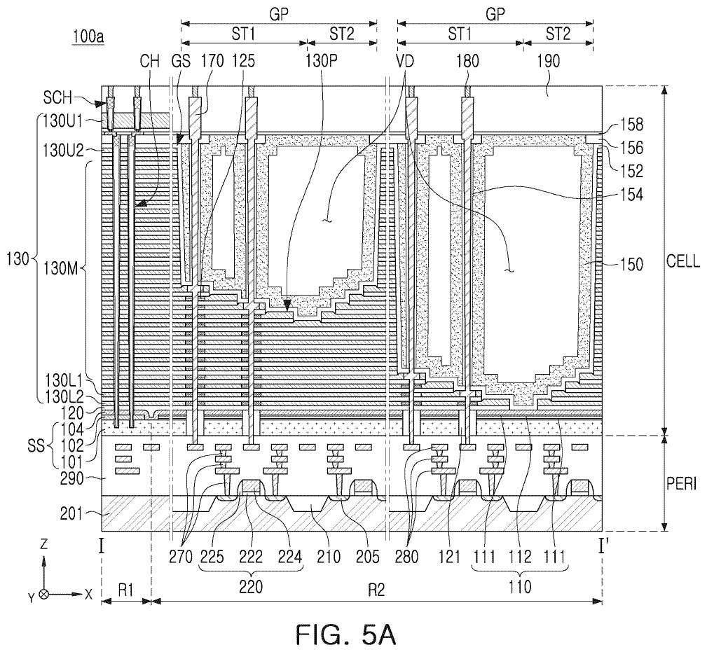

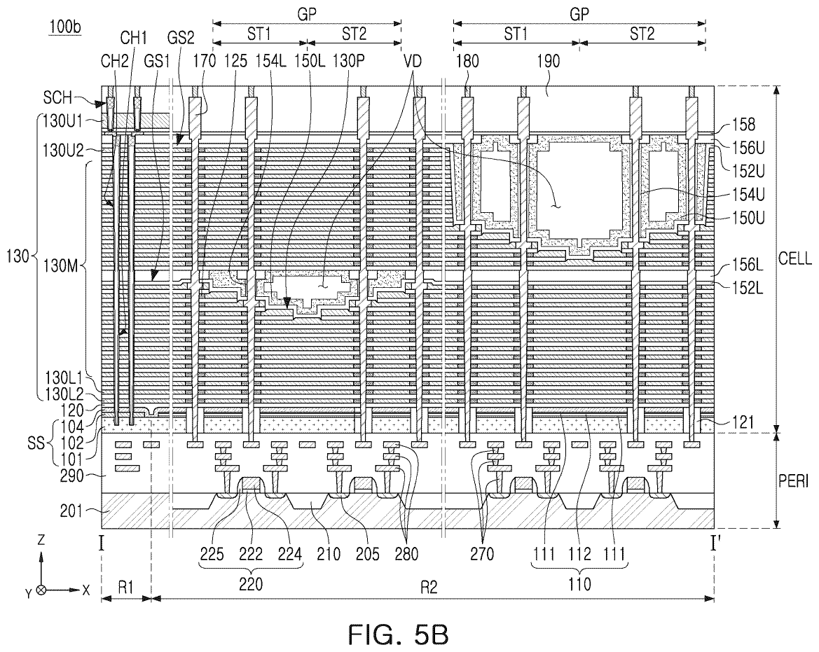

FIGS. 5A and 5B are cross-sectional views illustrating a semiconductor device according to some implementations, the illustrated cross-sectional views correspond to FIG. 2A.

Referring to FIG. 5A, in the semiconductor device 100a, in each staircase region GP, a slope of the first step structure ST1 may be smaller than a slope of the second step structure ST2. The staircase shape of first step structure ST1 may be relatively gentle, and the staircase shape of second step structure ST2 may be relatively steep.

Also, in some implementations, in the first step structure ST1, the gate electrodes 130 may be connected to the contact plugs 170, and in the second step structure ST2, the gate electrodes 130 may form a dummy region or a dummy structure not connected to the contact plugs 170. The relative inclination of the first and second step structures ST1 and ST2 and the arrangement position of the contact plugs 170 may be independently combined with other implementations.

Referring to FIG. 5B, the semiconductor device 100b includes first and second stack structures GS1 and GS2, first and second gap-fill insulating layers 150L and 150U, first lower and upper cell insulating layers 152L and 152U, second lower and upper cell insulating layers 154L and 154U, and third lower and upper cell insulating layers 156L and 156U, disposed in upper and lower portions, respectively.

In some implementations, the number of stack structures GS1 and GS2 stacked in the Z-direction may be varied. For example, in some implementations, the gate electrodes 130 may form three or more stack structures. The number of gate electrodes 130 included in the first stack structures GS1 and the number of gate electrodes 130 included in the first stack structures GS2 may be the same or different.

The gate electrodes 130 may have a shape removed by a predetermined depth from an upper portion of one of the first and second stack structures GS1 and GS2 in the staircase regions GP. The staircase regions GP may be disposed so as not to overlap each other in the Z-direction. On the staircase region GP of the first stack structure GS1, at least a portion of the gate electrodes 130 included in the upper second stack structures GS2 may extend horizontally. In some implementations, the arrangement type, the arrangement order, and the depth of the staircase regions GP may be varied. In some implementations, the gate electrodes 130 may not be disposed on the staircase regions GP.

The first channel structures CH includes vertically stacked lower and upper channel structures CH1 and CH2. The first channel structures CH may have a form in which the lower channel structures CH1 and the upper channel structures CH2 are connected to each other, and may have a bent portion due to a difference in width in the connection region.

The contact plugs 170 may have a shape corresponding to the channel structures CH. Each of the contact plugs 170 may include a lower region and an upper region penetrating through the first and second stack structures GS1 and GS2, respectively.

A first gap-fill insulating layer 150L, a first lower cell insulating layer 152L, a second lower cell insulating layers 154L, and a third lower cell insulating layer 156L may be disposed on the first stack structure GS1. A second gap-fill insulating layer 150U, a first upper cell insulating layer 152U, a second upper cell insulating layer 154U, and a third upper cell insulating layer 156U may be disposed on the second stack structure GS2. The first gap-fill insulating layer 150L may fill the staircase region GP of the first stack structure GS1, and the second gap-fill insulating layer 150U may fill the staircase region GP of the second stack structure GS2. The descriptions described with reference to FIGS. 2A to 3B may be applied to the first lower and upper cell insulating layers 152L and 152U, the second lower and upper cell insulating layers 154L and 154U, and the third lower and upper cell insulating layers 156L and 156U in addition to the above differences.

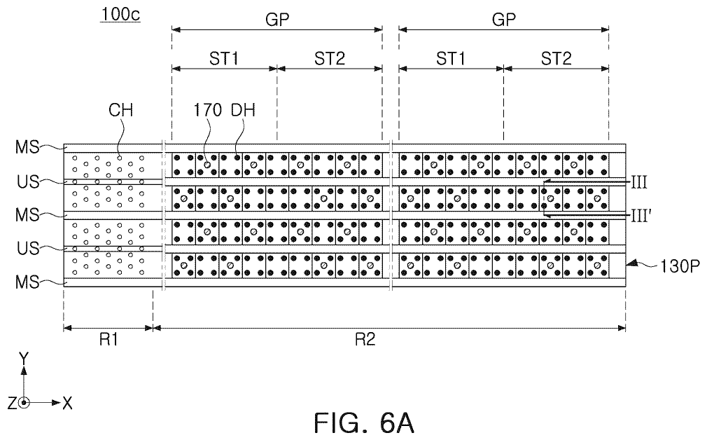

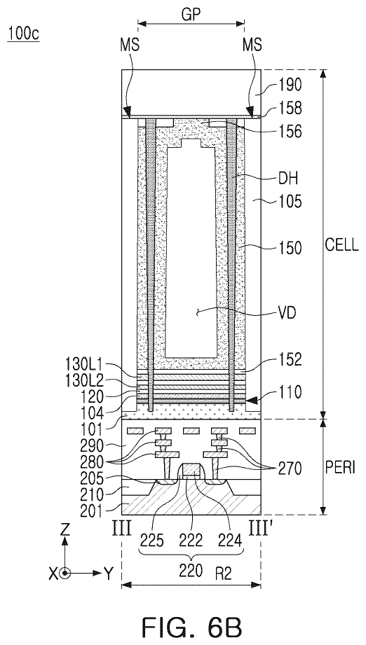

FIGS. 6A and 6B are a plan view and a cross-sectional view, respectively, illustrating a semiconductor device according to some implementations, taken along line III-III′ in FIG. 6A.

Referring to FIGS. 6A and 6B, in the semiconductor device 100c, the memory cell region CELL further includes support structures DH.

The support structures DH may be disposed on corners of each of contact regions 130P in a second region R2, as illustrated in FIG. 6A. The support structures DH may be disposed such that four support structures DH may surround a contact plug 170. However, the arrangement type and the size of support structures DH may be varied in some implementations. For example, in some implementations, the support structures DH may be disposed on an end of gate electrodes 130.

The support structures DH may be disposed below the horizontal insulating layer 158 and may support a mold structure including the interlayer insulating layers 120 during a process of manufacturing the semiconductor device 100c. The support structures DH may be referred to as a vertical structure along with the contact plugs 170 and/or the first channel structures CH. The support structures DH may penetrate through the stack structure GS, the second horizontal conductive layer 104, and the horizontal sacrificial layer 110, and lower ends of the support structures DH may be disposed in the plate layer 101. Upper ends of the support structures DH may be disposed on substantially the same level as a level of upper ends of the first channel structures CH, but implementations are not limited thereto. The support structures DCH may include an insulating material, and may include, for example, silicon oxide, silicon nitride, silicon carbide, or silicon oxynitride.

The gap-fill insulating layer 150 has voids VD disposed between the support structures DH. The voids VD may be isolated from the support structures DH. In cross-sections not illustrated, the voids VD may further be disposed between the stack structure GS and the support structures DH and also between the contact plugs 170 and the support structures DH. In some implementations, the voids VD may further be disposed between the support structures DH and the first isolation regions MS.

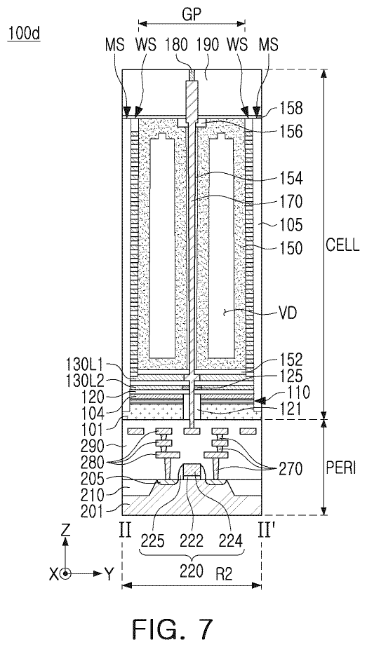

FIG. 7 is a cross-sectional view illustrating a semiconductor device according to some implementations, the illustration in FIG. 7 may correspond to a region illustrated in FIG. 2B.

Referring to FIG. 7, in the semiconductor device 100d, a stack structure GS includes wall regions WS.

The wall regions WS may be disposed on both side surfaces of the first isolation regions MS in the Y-direction. The wall regions WS may have a form in which the entirety of the gate electrodes 130 below the second select gate electrode 130U2 may be stacked, and the gate electrodes 130 included in the wall regions WS may be connected to the gate electrodes 130 included in the staircase regions GP. Accordingly, a length of the staircase regions GP in the Y-direction may be less than a length between adjacent first isolation regions MS in the Y-direction. In some implementations, relative lengths of the wall regions WS and the first isolation regions MS in the Y-direction may be varied.

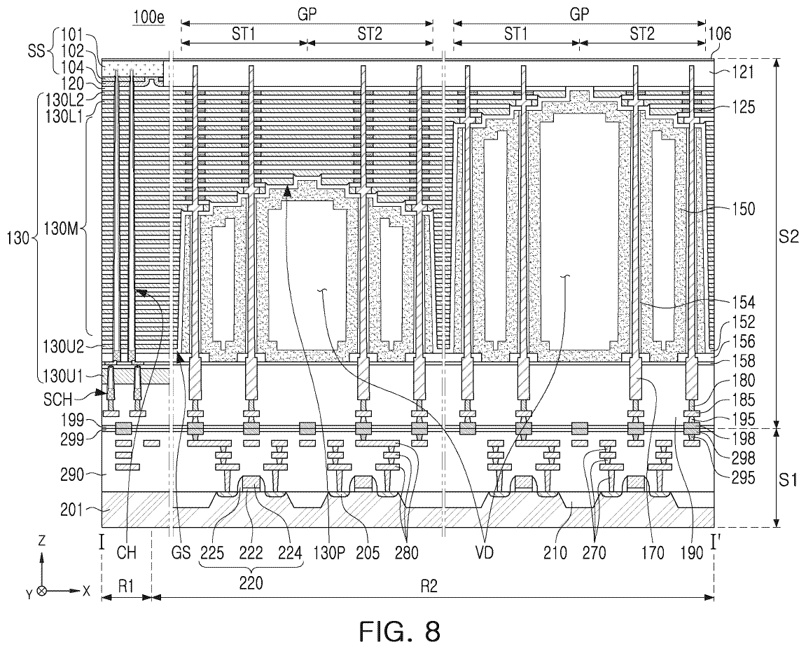

FIG. 8 is a cross-sectional view illustrating a semiconductor device according to some implementations.

Referring to FIG. 8, a semiconductor device 100e includes a first semiconductor structure S1 and a second semiconductor structure S2 bonded to each other by a wafer bonding method.

The description of the peripheral circuit region PERI described in the aforementioned implementations with reference to FIGS. 1 to 2B may be applied to the first semiconductor structure S1. However, the first semiconductor structure S1 may further include first bonding vias 295, first bonding metal layers 298, and first bonding insulating layer 299, which are bonding structures. The first bonding vias 295 may be disposed above the uppermost circuit interconnection lines 280 and may be connected to the circuit interconnection lines 280. At least a portion of the first bonding metal layers 298 may be connected to the first bonding vias 295 on the first bonding vias 295. The first bonding metal layers 298 may be connected to the second bonding metal layers 198 of the second semiconductor structure S2. The bonding metal layers 298 may provide, together with the second bonding metal layers 198, an electrical connection path according to bonding between the first semiconductor structure S1 and the second semiconductor structure S2. A portion of the first bonding metal layers 298 may be disposed for bonding without being connected to the lower circuit interconnection lines 280. The first bonding vias 295 and the first bonding metal layers 298 may include a conductive material such as copper (Cu). A first bonding insulating layer 299 may be disposed around the first bonding metal layers 298. The first bonding insulating layer 299 may also function as a diffusion barrier of the first bonding metal layers 298, and may include, for example, at least one of SiN, SiON, SiCN, SiOC, SiOCN, and SiO.

As for the second semiconductor structure S2, the description of the memory cell region CELL described in the aforementioned implementations with reference to FIGS. 1 to 4B may be applied unless otherwise indicated. The second semiconductor structure S2 may further include cell interconnection lines 185, which is a cell interconnection structure, and may further include second bonding vias 195, second bonding metal layers 198, and second bonding insulating layer 199, which are bonding structures. The second semiconductor structure S2 may further include a passivation layer 106 covering an upper surface of the plate layer 101.

The cell interconnection lines 185 may be connected to studs 180. However, in some implementations, the number of layers and the arrangement form of plugs and interconnection lines included in the cell interconnection structure may be varied. The cell interconnection lines 185 may be formed of a conductive material, and may include, for example, at least one of tungsten (W), aluminum (Al), and copper (Cu).

The second bonding vias 195 and the second bonding metal layers 198 may be disposed below uppermost cell interconnection lines 185. The second bonding vias 195 may connect the cell interconnection lines 185 to the second bonding metal layers 198, and the second bonding metal layers 198 may be bonded to the first bonding metal layers 298 of the first semiconductor structure S1. The second bonding insulating layer 199 may be bonded and connected to the first bonding insulating layer 299 of the first semiconductor structure S1. The second bonding vias 195 and the second bonding metal layers 198 may include a conductive material such as copper (Cu). The second bonding insulating layer 199 may include, for example, at least one of SiO, SiN, SiCN, SiOC, SiON, and SiOCN.

The first and second semiconductor structures S1 and S2 may be bonded to each other by bonding between the first bonding metal layers 298 and the second bonding metal layers 198 and bonding between the first bonding insulating layer 299 and the second bonding insulating layer 199. The bonding between the first bonding metal layers 298 and the second bonding metal layers 198 may be, for example, copper (Cu)-to-copper (Cu) bonding, and the bonding between the first bonding insulating layer 299 and the second bonding insulating layer 199 may be, for example, dielectric-to-dielectric bonding such as SiCN-to-SiCN bonding. The first and second semiconductor structures S1 and S2 may be bonded to each other by hybrid bonding including copper (Cu)-to-copper (Cu) bonding and dielectric-to-dielectric bonding.

The passivation layer 106 may be disposed on an upper surface of the plate layer 101 and may protect the semiconductor device 100f. The passivation layer 106 may include an insulating material such as at least one of silicon oxide, silicon nitride, and silicon carbide. The substrate insulating layer 121 may be relatively widely disposed in the second region R2 to cover upper ends of the contact plugs 170. However, in some implementations, the arrangement form of the substrate insulating layer 121 may be varied in the range of electrically isolating the contact plugs 170 from the plate layer 101.

In some implementations, the second semiconductor structure S2 may not include the first and second horizontal conductive layers 102 and 104 (see FIG. 2A). The first channel structures CH may be directly connected to the plate layer 101 while the first channel layers 140 (see FIG. 4B) is exposed through an upper end. However, the electrical connection form between the first channel structures CH and the common source line may be varied in some implementations, and the first channel structures and the source structure may have the same structure as in the implementations in FIG. 2A.

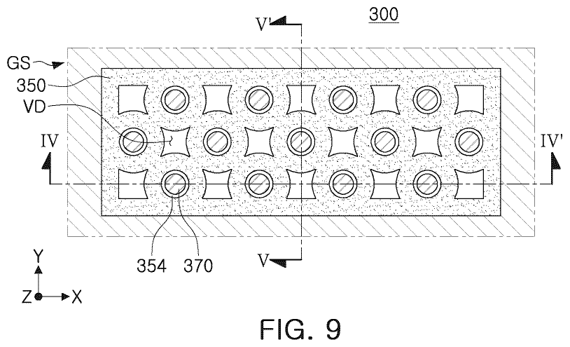

FIG. 9 is a cross-sectional view illustrating a semiconductor device according to some implementations.

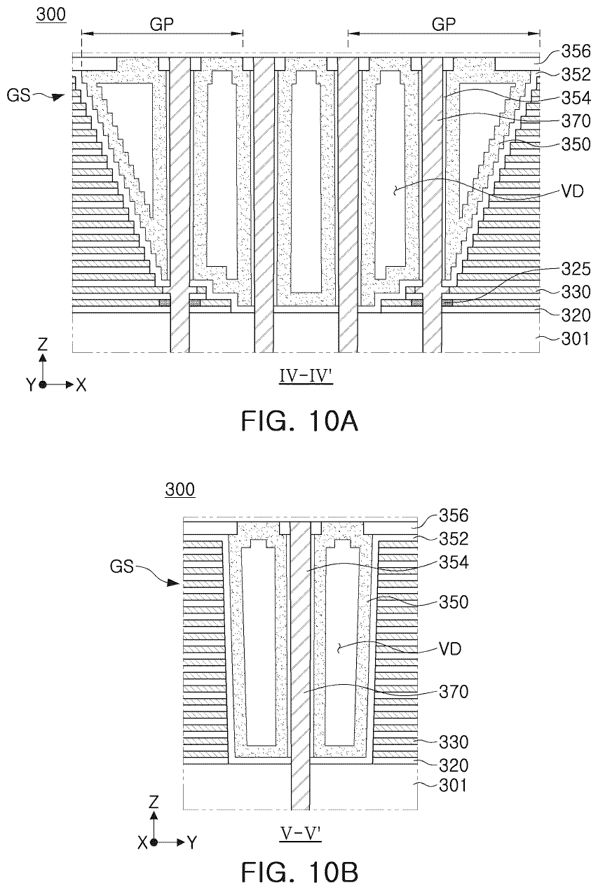

FIGS. 10A and 10B are cross-sectional views illustrating a semiconductor device according to some implementations, taken along lines IV-IV′ and V-V′, respectively, in FIG. 9.

Referring to FIGS. 9 to 10B, a semiconductor device 300 includes a stack structure GS on a substrate 301 and having staircase regions GP, vertical structures 370 penetrating through a portion of the stack structure GS or extending vertically between the staircase regions GP, and a gap-fill insulating layer 350 filling the gap-fill insulating layer between the staircase regions GP and the staircase regions GP. The semiconductor device 300 includes a first insulating layer 352 covering the stack structure GS, a second insulating layer 354 covering the side surfaces of the vertical structures 370, a third insulating layer 356 on the stack structure GS, and a surface insulating layers 325 surrounding a portion of a side surface of the vertical structures 370.

The stack structure GS includes first and second layers 320 and 330 alternately stacked. For example, the first layers 320 may be insulating layers and the second layers 330 may be conductive layers. The stack structure GS may have staircase regions GP having step structures on an ends opposing each other.

The vertical structures 370 may penetrate through the gap-fill insulating layer 350 between the staircase regions GP and the staircase regions GP and may extend downward. The vertical structures 370 may penetrate through at least a portion of the substrate 301, but some implementations thereof is not limited thereto. When the vertical structures 370 include a conductive material, the vertical structures 370 may be electrically connected to the second layers 330. In this case, the vertical structures 370 may have a horizontally extended form in a region connected to the second layers 330, but the connection form is not limited thereto. Side-surface insulating layers 325 may be disposed between the second layers 330 and the vertical structures 370 not connected to the vertical structures 370. When the vertical structures 370 include an insulating material, the vertical structures 370 may not be electrically connected to the stack structure GS.

The gap-fill insulating layer 350 may be disposed with a substantially uniform thickness along side surfaces of the stack structure GS and side surfaces of the second insulating layers 354 on the vertical structures 370. A portion of an upper surface of the gap-fill insulating layer 350 may be disposed on substantially the same level as a level of upper ends of the vertical structures 370, and another portion of the upper surface of the gap-fill insulating layer 350 may be disposed on a level lower than a level of the upper ends of the vertical structures 370, for example, may be disposed on substantially the same level as a level of a lower surface of the third insulating layer 356.

The gap-fill insulating layer 350 includes voids VD spaced apart from the stack structure GS and the vertical structures 370. As illustrated in FIG. 9, the voids VD may be spaced apart from the stack structure GS and the vertical structures 370. The voids VD may be spaced apart from the first and second layers 320, 230. As illustrated in FIG. 10B, the voids VD may be disposed symmetrically with respect to one of the vertical structures 370 and/or a center of the illustrated region.

Also, the descriptions of the gap-fill insulating layer 150 and the first to third cell insulating layers 152, 154, and 156 described with reference to FIGS. 1 to 4B may be applied to a description of the gap-fill insulating layer 350 and the first to third insulating layers 352, 354, and 356, respectively.

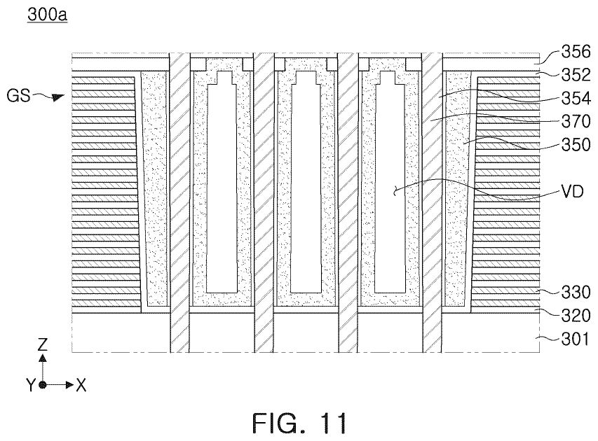

FIG. 11 is a cross-sectional view illustrating a semiconductor device according to some implementations. The illustration of FIG. 11 may be a cross-sectional view corresponding to the illustration of FIG. 10A.

Referring to FIG. 11, a semiconductor device 300a may not include a staircase region GP, different from the implementations in FIG. 10A. The vertical structures 370 may extend by penetrating through the gap-fill insulating layer 350, rather than penetrating through the second layers 330. As such, the gap-fill insulating layer 350 including voids VD may be applied even when a region other than a staircase region is filled.

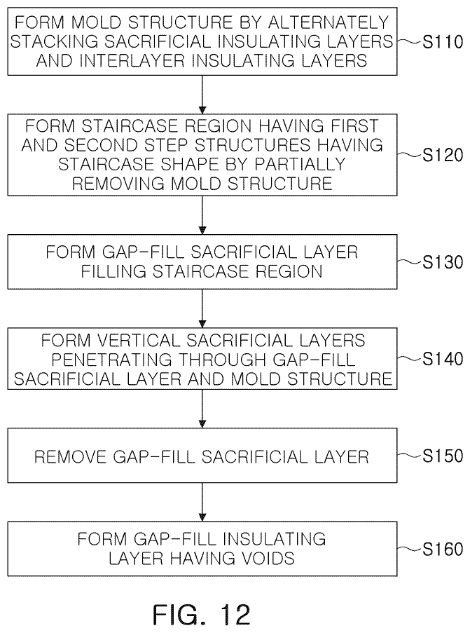

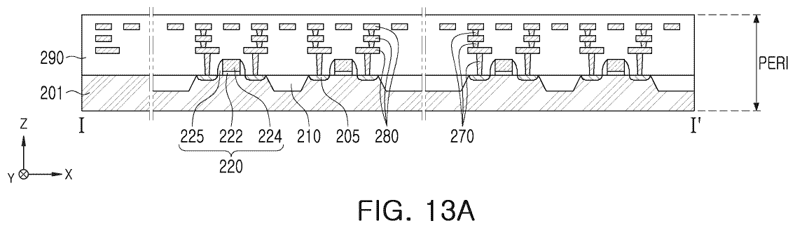

FIG. 12 is a flowchart illustrating a method of manufacturing a semiconductor device according to some implementations.

FIGS. 13A to 13O are cross-sectional views illustrating a method of manufacturing a semiconductor device according to some implementations. The illustration of FIGS. 13A to 13O may be a cross-sectional view corresponding to the illustration of FIG. 2A.

Referring to FIG. 13A, circuit devices 220, a circuit interconnection structure, and a peripheral region insulating layer 290 included in a peripheral circuit region PERI may be formed on a substrate 201.

First, device isolation layers 210 may be formed in the substrate 201, and a circuit gate dielectric layer 222 and a circuit gate electrode 225 may be formed in order on the substrate 201. The device isolation layers 210 may be formed by, for example, a shallow trench isolation (STI) process. The circuit gate dielectric layer 222 and the circuit gate electrode 225 may be formed using atomic layer deposition (ALD) or chemical vapor deposition (CVD). The circuit gate dielectric layer 222 may be formed of silicon oxide, and the circuit gate electrode 225 may be formed of at least one of polycrystalline silicon or a metal silicide layer, but implementations are not limited thereto. Thereafter, a spacer layer 224 and impurity regions 205 may be formed on both side walls of the circuit gate dielectric layer 222 and the circuit gate electrode 225. In some implementations, the spacer layer 224 may include a plurality of layers. The impurity regions 205 may be formed by performing an ion implantation process.

The circuit contact plugs 270 of the circuit interconnection structure may be formed by partially forming the peripheral region insulating layer 290, removing a portion thereof by etching, and filling a conductive material therein. The circuit interconnection lines 280 may be formed, for example, by depositing a conductive material and patterning the conductive material.

The peripheral region insulating layer 290 may include a plurality of insulating layers. The peripheral region insulating layer 290 may become a portion in each process of forming the circuit interconnection structure. Accordingly, a peripheral circuit region PERI may be formed.

Referring to FIGS. 12 and 13B, a plate layer 101 provided with a memory cell region CELL, a horizontal sacrificial layer 110, a second horizontal conductive layer 104, and a substrate insulating layer 121 may be formed on the peripheral circuit region PERI, and a mold structure PS may be formed by alternately stacking the sacrificial insulating layers 118 and the interlayer insulating layers 120 (S110).

The plate layer 101 may be formed on the peripheral region insulating layer 290. The plate layer 101 may be formed of, for example, polycrystalline silicon and may be formed by a CVD process. Polycrystalline silicon included in the plate layer 101 may include impurities.

The first and second horizontal sacrificial layers 111 and 112 included in the horizontal sacrificial layer 110 may be alternately stacked on the plate layer 101. A portion of the horizontal sacrificial layer 110 may be replaced with the first horizontal conductive layer 102 in FIG. 2A through a subsequent process. The first horizontal sacrificial layers 111 may include a material different from that of the second horizontal sacrificial layer 112. For example, the first horizontal sacrificial layers 111 may be formed of the same material as that of the interlayer insulating layers 120, and the second horizontal sacrificial layer 112 may be formed of the same material as that of the subsequent sacrificial insulating layers 118. A portion of the horizontal sacrificial layer 110 may be removed by a patterning process in partial regions, for example, a second region R2.

The second horizontal conductive layer 104 may be formed on the horizontal sacrificial layer 110 and may be in contact with the plate layer 101 in a region from which the horizontal sacrificial layer 110 is removed.

The substrate insulating layer 121 may be formed to penetrate through the plate layer 101 in partial regions including a region in which the contact plugs 170 (see FIG. 2A) are disposed. The substrate insulating layer 121 may be formed by removing a portion of the plate layer 101, the horizontal sacrificial layer 110, and the second horizontal conductive layer 104 and filling an insulating material. After filling the insulating material, a planarization process may be further performed using a chemical mechanical polishing (CMP) process. Accordingly, an upper surface of the substrate insulating layer 121 may be substantially coplanar with an upper surface of the second horizontal conductive layer 104.

At least a portion of the sacrificial insulating layers 118 may be replaced with gate electrodes 130 (see FIG. 2A) through a subsequent process. The sacrificial insulating layers 118 may be formed of a material different from that of the interlayer insulating layers 120, and may be formed of a material etched with etch selectivity under specific etching conditions with respect to the interlayer insulating layers 120. For example, the interlayer insulating layers 120 may be formed of at least one of silicon oxide and silicon nitride, and the sacrificial insulating layers 118 may be formed of a material different from that of the interlayer insulating layers 120 selected from among silicon, silicon oxide, silicon carbide, and silicon nitride. In some implementations, the interlayer insulating layers 120 may not have the same thickness. The thickness of the interlayer insulating layers 120 and the sacrificial insulating layers 118 and the number of films included therein may be varied from the illustrated examples.

Referring to FIGS. 12 and 13C, staircase regions GP having first and second step structures ST1 and ST2 having a staircase shape may be formed by partially removing the mold structure PS (S120), and a first cell insulating layer 152 may be formed.

The staircase regions GP may be formed by repeatedly performing a photolithography process and an etching process for a mold structure PS. The staircase regions GP may be formed in the second region R2 and may be formed to include a region in which the upper sacrificial insulating layers 118 may extend shorter than the lower sacrificial insulating layers 118. In each staircase region GP, first and second step structures ST1 and ST2 symmetrical to each other may be formed such that upper surfaces and ends of the plurality of sacrificial insulating layers 118 may exposed upwardly. However, in some implementations, the specific shape of the staircase regions GP may be varied as in the some implementations in FIG. 3A. By further forming sacrificial insulating layers 118 on the first and second step structures ST1 and ST2 of the staircase regions GP, the sacrificial insulating layers 118 disposed in the uppermost portion of each region may have a relatively great thickness.

The first cell insulating layer 152 may be formed by, for example, an ALD process, and may be conformally formed along the first and second step structures ST1 and ST2.

Referring to FIGS. 12 and 13D, gap-fill sacrificial layers 116 filling the staircase regions GP may be formed (S130) and a third cell insulating layer 156 may be formed.

The gap-fill sacrificial layers 116 may be formed by being deposited to fill the staircase regions GP and being planarized. The gap-fill sacrificial layers 116 may be selected from a material for filling, for example, the staircase regions GP having a depth of 1 μm or more, such as 10 μm or more, without voids and cusping. Also, as the gap-fill sacrificial layers 116, a material etched at an appropriate etching rate during a subsequent cryogenic etch process may be selected. The gap-fill sacrificial layers 116 may include, for example, N-type doped polycrystalline silicon.

The third cell insulating layer 156 may be formed to cover an upper surface of the first cell insulating layer 152 on the mold structure PS and may cover an upper surface of the gap-fill sacrificial layer 116.

Referring to FIGS. 12 and 13E to 13G, vertical sacrificial layers 119 penetrating through the gap-fill sacrificial layers 116 and the mold structure PS may be formed (S140).

First, referring to FIG. 13E, through-holes OH penetrating through the gap-fill sacrificial layers 116 and the mold structure PS may be formed.

The through-holes OH may be formed in regions corresponding to the first channel structures CH and the contact plugs 170 in FIG. 2A. The through-holes OH may be formed, for example, by a cryogenic etch process. The through-holes OH may further penetrate through the third cell insulating layer 156, the first cell insulating layer 152, and the substrate insulating layer 121. The circuit interconnection lines 280 may be exposed through bottom surfaces of the through-holes OH. Since the through-holes OH are formed by penetrating through the gap-fill sacrificial layers 116, which is advantageous for the cryogenic etch process, the through-holes OH may be formed to have a pillar-shaped hole shape without distortion and distortion.

Referring to FIG. 13F, second cell insulating layers 154 may be formed around the through-holes OH.

The second cell insulating layers 154 may be formed by oxidizing the gap-fill sacrificial layers 116 exposed through the through-holes OH. Accordingly, the second cell insulating layers 154 may be formed only on a surface of the gap-fill sacrificial layers 116. For example, the gap-fill sacrificial layers 116 may be silicon oxide layers.

Referring to FIG. 13G, vertical sacrificial layers 119 may be formed by filling the through-holes OH.

The vertical sacrificial layers 119 may include materials different from those of the gap-fill sacrificial layers 116, the second cell insulating layers 154, and the third cell insulating layer 156. The vertical sacrificial layers 119 may include, for example, a metal material or a carbon-based material. The vertical sacrificial layers 119 may be formed by filling the through-holes OH with the aforementioned material and performing a planarization process.

Referring to FIGS. 12 and 13H, openings OP may be formed in the third cell insulating layer 156, and the gap-fill sacrificial layers 116 may be removed through the openings OP (S150).

First, the openings OP may be formed by partially removing the third cell insulating layer 156 on the gap-fill sacrificial layers 116. The size and the number of the openings OP are not limited to the illustrated examples in the drawings, and may be varied in some implementations.

The gap-fill sacrificial layers 116 may be selectively removed with respect to the first cell insulating layer 152 and the second cell insulating layer 154 using, for example, a wet etching process.

Referring to FIGS. 12 and 13I, the gap-fill insulating layers 150 having voids VD may be formed in a region from which the gap-fill sacrificial layers 116 are removed (S160).

The gap-fill insulating layers 150 may be substantially conformally formed along the first cell insulating layer 152 and the second cell insulating layer 154. For example, the gap-fill insulating layers 150 may be formed using an ALD process. The voids VD may be formed in the gap-fill insulating layers 150 and may have a shape corresponding to that of the staircase regions GP in at least some regions.

Referring to FIG. 13J, first channel structures CH may be formed.

The first channel structures CH may be formed by forming lower channel holes by removing the vertical sacrificial layers 119 from the first region R1, and depositing at least a portion of the first gate dielectric layer 145, the first channel layer 140, the first channel layer 140, the first channel filling insulating layer 147 and the first channel pad 149 in order.

The first gate dielectric layer 145 may be formed to have a uniform thickness using an ALD or CVD process. In this process, the entirety or a portion of the first gate dielectric layer 145 may be formed, and a portion extending perpendicularly to the plate layer 101 along first channel structures CH may be formed in this process. The first channel layer 140 may be formed on the first gate dielectric layer 145 in the lower channel holes. The first channel filling insulating layer 147 may be formed to fill the lower channel holes and may be an insulating material. The first channel pad 149 may be formed of a conductive material, for example polycrystalline silicon.

Referring to FIG. 13K, the vertical sacrificial layers 119 may be removed, preliminary side-surface insulating layers 125P and vertical sacrificial layers 191 may be formed, and sacrificial insulating layers 118 may be removed.

First, vertical sacrificial layers 119 in the through-holes OH may be removed from the second region R2, and exposed sacrificial insulating layers 118 may be partially removed. Contact tunnel portions may be formed by removing the sacrificial insulating layers 118 to a predetermined length around the through-holes OH. The contact tunnel portions may be formed to have a relatively short length in the uppermost sacrificial insulating layers 118 and to have a relatively long length in the lower sacrificial insulating layers 118.

Specifically, initially, conversely, the contact tunnel portions may be formed to have a relatively long length in the uppermost sacrificial insulating layers 118. This may be because the uppermost sacrificial insulating layers 118 may include a region having a relatively faster etching rate than that of the sacrificial insulating layers 118 therebelow. Thereafter, another sacrificial layer may be formed in the through-holes OH and the contact tunnel portions. The sacrificial layer may be formed of a material having an etching rate lower than that of the sacrificial insulating layers 118. Thereafter, a portion of the sacrificial layer and the sacrificial insulating layers 118 may be removed. In this case, the sacrificial layer may remain in the uppermost portion, the sacrificial layer may be removed and the sacrificial insulating layers 118 may be partially removed in a lower portion. Accordingly, finally, the contact tunnel portions may be formed to have a relatively short length in the uppermost sacrificial insulating layers 118.

Preliminary side-surface insulating layers 125P may be formed by depositing an insulating material in the through-holes OH and the contact tunnel portions. The preliminary side-surface insulating layers 125P may be formed on a side wall of the through-holes OH and may fill the contact tunnel portions. In the uppermost sacrificial insulating layers 118, the preliminary side-surface insulating layers 125P may not completely fill the contact tunnel portions.

The vertical sacrificial layers 191 may fill the through-holes OH and may fill the uppermost contact tunnel portions. The vertical sacrificial layers 191 may include a material different from that of the preliminary side-surface insulating layers 125P, and may include, for example, polycrystalline silicon.

Thereafter, openings penetrating through the sacrificial insulating layers 118 and the interlayer insulating layers 120 and extending to the plate layer 101 may be formed in the position of the first isolation regions MS (see FIGS. 1 and 2B). Thereafter, the horizontal sacrificial layer 110 may be selectively removed from the first region R1 by performing an etch-back process while forming sacrificial spacer layers in the openings, and a portion of the exposed first gate dielectric layer 145 may be removed together. A first horizontal conductive layer 102 may be formed by depositing a conductive material in the region from which the horizontal sacrificial layer 110 is removed, and the sacrificial spacer layers may be removed from the openings. Through this process, a first horizontal conductive layer 102 may be formed in the first region R1.

Thereafter, the sacrificial insulating layers 118 may be selectively removed with respect to the interlayer insulating layers 120, the second horizontal conductive layer 104, and the preliminary side-surface insulating layers 125P using, for example, wet etching.

Referring to FIG. 13L, a portion of the gate electrodes 130 may be formed.

In this process, gate electrodes 130 excluding the first select gate electrode 130U1 may be formed. The gate electrodes 130 may be formed by depositing a conductive material in regions from which the sacrificial insulating layers 118 are removed. The conductive material may include a metal, polycrystalline silicon or metal silicide material. In some implementations, a portion of the first gate dielectric layer 145 may be first formed before forming the gate electrodes 130.

After forming the gate electrodes 130, gate isolation insulating layers 105 (see FIG. 2B) may be formed in the openings formed to correspond to the first isolation regions MS.

Referring to FIG. 13M, a horizontal insulating layer 158 and a first upper gate electrode 130U1 may be formed, and second channel structures SCH penetrating through the first upper gate electrode 130U1 may be formed.

The horizontal insulating layer 158 may be formed on the first channel structures CH. Thereafter, the upper insulating layer 190 may be partially formed and the first upper gate electrode 130U1 may be patterned and formed. The first upper gate electrode 130U1 may include a different material from that of the other gate electrodes 130, but some implementations thereof is not limited thereto. For example, the first upper gate electrode 130U1 may include polycrystalline silicon. Thereafter, an upper insulating layer 190 may be additionally formed.

To form the second channel structures SCH, first, upper channel holes penetrating through the first upper gate electrode 130U1 may be formed, and second channel dielectric layers 165 and sacrificial layers may be formed in order. Thereafter, lower holes penetrating through the second channel dielectric layers 165 and the sacrificial layers and extending to the horizontal insulating layer 158 may be formed on bottom surfaces of the upper channel holes, and first channel pads 149 may be exposed by partially removing the horizontal insulating layer 158 exposed through the lower holes. Connection pads 161 may be formed in regions from which the horizontal insulating layer 158 is removed, the sacrificial layers may be removed, a second channel layer 160, a second channel filling insulating layer 167, and a second channel pad 169 may be formed in order in each of the upper channel holes, thereby forming second channel structures SCH. Each layer may be formed in the same manner as in the first channel structures CH. The second channel layers 160 may be connected to connection pads 161 in a lower portion.

Referring to FIG. 13N, upper openings UP may be formed.

The upper openings UP may be formed to penetrate through the upper insulating layer 190. Specifically, the upper openings UP may penetrate through the upper insulating layer 190 and the horizontal insulating layer 158 in a position corresponding to the contact plugs 170 in FIG. 2A and may be formed such that the preliminary contact insulating layers 125P and the vertical sacrificial layers 191 may be exposed. A depth of each of the upper openings UP may be varied in some implementations. For example, in some implementations, lower ends of the upper openings UP may be disposed below the third cell insulating layer 156.

Referring to FIG. 13O, the vertical sacrificial layers 191 may be removed from the through-holes OH and contact plugs 170 may be formed.

The vertical sacrificial layers 191 may be selectively removed with respect to the interlayer insulating layers 120 and the gate electrodes 130. After the vertical sacrificial layers 191 are removed, a portion of the exposed preliminary side-surface insulating layers 125P may also be removed. In this case, the entirety of the preliminary side-surface insulating layers 125P may be removed from the contact regions 130P, and the preliminary side-surface insulating layers 125P therebelow may remain and may form side-surface insulating layers 125. In the contact regions 130P, when the first gate dielectric layer 145 is exposed after the preliminary side-surface insulating layers 125P are removed, the first gate dielectric layer 145 may also be removed such that side surfaces of the gate electrodes 130 may be exposed.

The contact plugs 170 may be formed by depositing a conductive material in through-holes OH. The contact plugs 170 may be formed to have horizontal extensions 170H (see FIG. 3B) extending horizontally from the contact regions 130P, and accordingly, the contact plugs 170 may be physically and electrically connected to the gate electrodes 130.

Thereafter, referring to FIG. 2A together, by forming the studs 180 connected to upper ends of the contact plugs 170 and the first channel structures CH, the semiconductor device 100 may be manufactured.

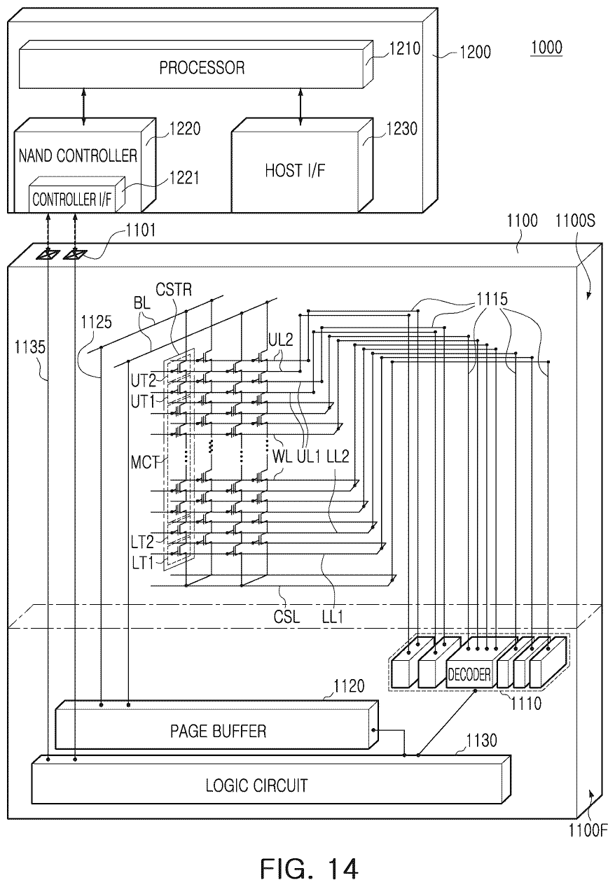

FIG. 14 is a view illustrating a data storage system including a semiconductor device according to some implementations.

Referring to FIG. 14, a data storage system 1000 includes a semiconductor device 1100 and a controller 1200 electrically connected to the semiconductor device 1100. The data storage system 1000 may be implemented as a storage device including one or a plurality of semiconductor devices 1100 or an electronic device including a storage device. For example, the data storage system 1000 may be implemented as a solid state drive device (SSD) including one or a plurality of semiconductor devices 1100, a universal serial bus (USB), a computing system, a medical device, or a communication device.

The semiconductor device 1100 may be implemented as a non-volatile memory device, such as, for example, the NAND flash memory device described in the aforementioned example embodiment with reference to FIGS. 1 to 11. The semiconductor device 1100 includes a first structure 1100F and a second structure 1100S on the first structure 1100F. In some implementations, the first structure 1100F may be disposed on the side of the second structure 1100S. The first structure 1100F may be implemented as a peripheral circuit structure including a decoder circuit 1110, a page buffer 1120, and a logic circuit 1130. The second structure 1100S may be implemented as a memory cell structure including a bitline BL, a common source line CSL, wordlines WL, first and second gate upper lines UL1 and UL2, first and second gate lower lines LL1 and LL2 and memory cell strings CSTR disposed between the bitline BL and the common source line CSL.

In the second structure 1100S, each of the memory cell strings CSTR includes lower transistors LT1 and LT2 adjacent to the common source line CSL, upper transistors UT1 and UT2 adjacent to the bitline BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be varied in some implementations.

In some implementations, the upper transistors UT1 and UT2 may include a string select transistor, and the lower transistors LT1 and LT2 may include a ground select transistor. The gate lower lines LL1 and LL2 may be configured as gate electrodes of the lower transistors LT1 and LT2, respectively. The wordlines WL may be configured as gate electrodes of the memory cell transistors MCT, and the gate upper lines UL1 and UL2 may be configured as gate electrodes of the upper transistors UT1 and UT2, respectively.

In some implementations, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT2 may be used in an erase operation for erasing data stored in the memory cell transistors MCT using a GIDL phenomenon.

The common source line CSL, the first and second gate lower lines LL1 and LL2, the wordlines WL, and the first and second gate upper lines UL1 and UL2 may be electrically connected to the decoder circuit 1110 through first connection interconnections 1115 extending from the first structure 1100F to the second structure 1100S. The bitlines BL may be electrically connected to the page buffer 1120 through second connection interconnections 1125 extending from the first structure 110F to the second structure 1100S.

In the first structure 1100F, the decoder circuit 1110 and the page buffer 1120 may perform a control operation on at least one selected memory cell transistor among the plurality of memory cell transistors MCT. The decoder circuit 1110 and the page buffer 1120 may be controlled by the logic circuit 1130. The semiconductor device 1100 may communicate with the controller 1200 through the input/output pad 1101 electrically connected to the logic circuit 1130. The input/output pads 1101 may be electrically connected to the logic circuit 1130 through an input/output connection line 1135 extending from the first structure 1100F to the second structure 1100S.

The controller 1200 includes a processor 1210, a NAND controller 1220, and a host interface 1230. In some implementations, the data storage system 1000 includes a plurality of semiconductor devices 1100, and in this case, the controller 1200 may control the plurality of semiconductor devices 1100.

The processor 1210 may control overall operation of the data storage system 1000 including the controller 1200. The processor 1210 may operate according to a predetermined firmware, and may access the semiconductor device 1100 by controlling the NAND controller 1220. The NAND controller 1220 includes a controller interface 1221 processing communication with the semiconductor device 1100. Through the controller interface 1221, a control command for controlling the semiconductor device 1100, data to be written to the memory cell transistors MCT of the semiconductor device 1100, and data to be read from the memory cell transistors MCT of the semiconductor device 1100 may be transmitted. The host interface 1230 may provide a communication function between the data storage system 1000 and an external host. When a control command from an external host is received through the host interface 1230, the processor 1210 may control the semiconductor device 1100 in response to the control command.

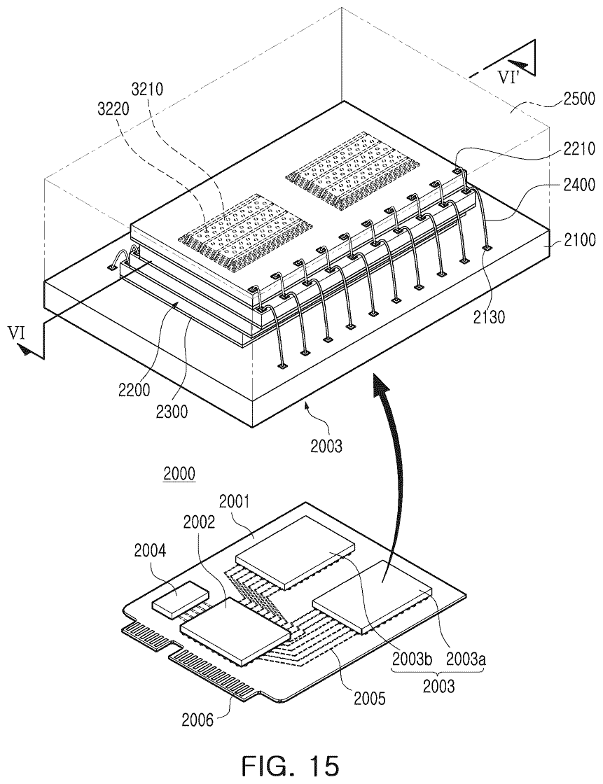

FIG. 15 is a perspective view illustrating a data storage system including a semiconductor device according to some implementations.

Referring to FIG. 15, a data storage system 2000 in some implementations includes a main board 2001, a controller 2002 mounted on the main board 2001, one or more semiconductor packages 2003, and a DRAM 2004. The semiconductor package 2003 and the DRAM 2004 may be connected to the controller 2002 by interconnection patterns 2005 formed on the main board 2001.

The main board 2001 includes a connector 2006 including a plurality of pins coupled to an external host. The number and arrangement of the plurality of pins in the connector 2006 may vary depending on a communication interface between the data storage system 2000 and the external host. In some implementations, the data storage system 2000 may communicate with an external host according to one of interfaces from among universal serial bus (USB), peripheral component interconnect express (PCI-Express), serial advanced technology attachment (SATA), M-Phy for universal flash storage (UFS). In some implementations, the data storage system 2000 may operate by power supplied from an external host through the connector 2006. The data storage system 2000 may further include a power management integrated circuit (PMIC) for distributing power supplied from the external host to the controller 2002 and the semiconductor package 2003.

The controller 2002 may write data to or may read data from the semiconductor package 2003, and may improve an operating speed of the data storage system 2000.

The DRAM 2004 may be configured as a buffer memory for alleviating a difference in speeds between the semiconductor package 2003, which is a data storage space, and an external host. The DRAM 2004 included in the data storage system 2000 may operate as a cache memory, and may provide a space for temporarily storing data in a control operation for the semiconductor package 2003. When the data storage system 2000 includes the DRAM 2004, the controller 2002 may further include a DRAM controller for controlling the DRAM 2004 in addition to the NAND controller for controlling the semiconductor package 2003.

The semiconductor package 2003 includes first and second semiconductor packages 2003a and 2003b spaced apart from each other. Each of the first and second semiconductor packages 2003a and 2003b may be configured as a semiconductor package including a plurality of semiconductor chips 2200. Each of the first and second semiconductor packages 2003a and 2003b includes a package substrate 2100, semiconductor chips 2200 on the package substrate 2100, adhesive layers 2300 disposed on lower surfaces of the semiconductor chips 2200, respectively, a connection structure 2400 electrically connecting the semiconductor chips 2200 to the package substrate 2100, and a molding layer 2500 covering the semiconductor chips 2200 and the connection structure 2400 on the package substrate 2100.

The package substrate 2100 may be configured as a printed circuit board including package upper pads 2130. Each semiconductor chip 2200 includes an input/output pad 2210. The input/output pad 2210 may correspond to the input/output pad 1101 in FIG. 14. Each of the semiconductor chips 2200 includes gate stack structures 3210 and channel structures 3220. Each of the semiconductor chips 2200 may include the semiconductor device described in the aforementioned example embodiment with reference to FIGS. 1 to 11.

In some implementations, the connection structure 2400 may be configured as a bonding wire electrically connecting the input/output pad 2210 to the upper package pads 2130. Accordingly, in each of the first and second semiconductor packages 2003a and 2003b, the semiconductor chips 2200 may be electrically connected to each other by a bonding wire method, and may be electrically connected to the package upper pads 2130 of the package substrate 2100. In some implementations, in each of the first and second semiconductor packages 2003a and 2003b, the semiconductor chips 2200 may be electrically connected to each other by a connection structure including a through-electrode (TSV) instead of the connection structure 2400 of a bonding wire method.

In some implementations, the controller 2002 and the semiconductor chips 2200 may be included in a single package. In some implementations, the controller 2002 and the semiconductor chips 2200 may be mounted on an interposer substrate different from the main board 2001, and the controller 2002 and the semiconductor chips 2200 may be connected to each other by interconnection formed on the interposer substrate.

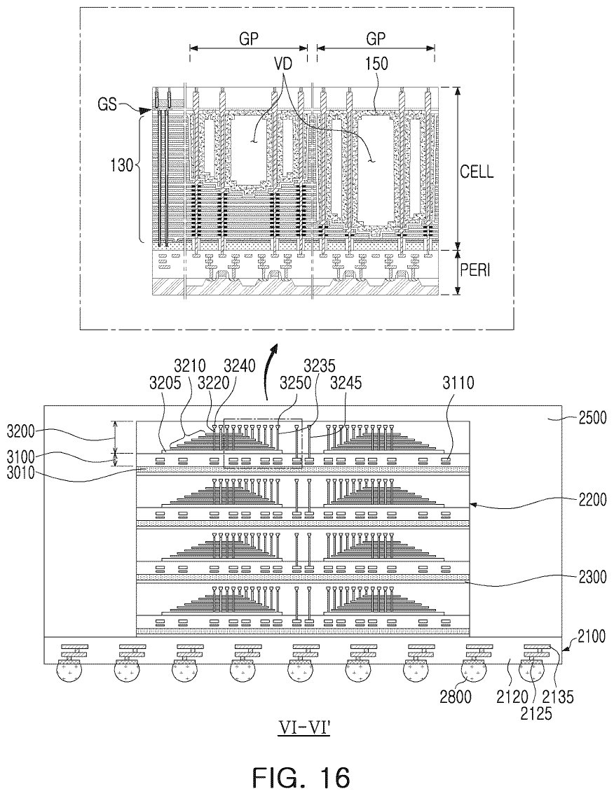

FIG. 16 is a cross-sectional view illustrating a semiconductor package according to some implementations. The illustration of FIG. 16 can correspond to some implementations of the semiconductor package 2003 in FIG. 15 taken along line VI-VI′.

Referring to FIG. 16, in the semiconductor package 2003, the package substrate 2100 may be implemented as a printed circuit substrate. The package substrate 2100 includes a package substrate body portion 2120, package upper pads 2130 (see FIG. 15) disposed on an upper surface of the package substrate body portion 2120, lower pads 2125 disposed on the lower surface of the package substrate body 2120 or exposed through the lower surface, and internal interconnections 2135 electrically connecting the upper pads 2130 to the lower pads 2125 in the package substrate body 2120. The lower pads 2125 may be connected to the interconnection patterns 2005 of the main the substrate 2001 of the data storage system 2000 through the conductive connection portions 2800 as illustrated in FIG. 15.

Each of the semiconductor chips 2200 includes a semiconductor substrate 3010 and a first structure 3100 and a second structure 3200 stacked in order on the semiconductor substrate 3010. The first structure 3100 may include a peripheral circuit region including peripheral interconnections 3110. The second structure 3200 includes a common source line 3205, a gate stack structure 3210 on the common source line 3205, channel structures 3220 penetrating through the gate stack structure 3210, bitlines 3240 electrically connected to the channel structures 3220, and contact plugs 3235 electrically connected to the wordlines WL (see FIG. 14) of the gate stack structure 3210. As described in the aforementioned example embodiment with reference to FIGS. 1 to 11, in each of the semiconductor chips 2200, the gap-fill insulating layer 150 filling the staircase regions GP of the gate electrodes 130 in each of the semiconductor chips 2200 includes the voids VD spaced apart from the contact plugs 170 and the stack structure GS therein.

Each of the semiconductor chips 2200 includes a through-interconnection 3245 electrically connected to the peripheral interconnections 3110 of the first structure 3100 and extending into the second structure 3200. The through-interconnection 3245 may be disposed on an external side of the gate stack structure 3210 and may further be disposed to penetrate through the gate stack structure 3210. Each of the semiconductor chips 2200 may further include an input/output pad 2210 (see FIG. 15) electrically connected to the peripheral interconnections 3110 of the first structure 3100.

According to the aforementioned implementations, by optimizing the material of the upper select gate electrode, the arrangement of the gate barrier layer, and the structure of the second channel structure penetrating through the upper select gate electrode, and a semiconductor device having improved electrical properties and reliability and a data storage system including the same may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

While implementations have been illustrated and described above, it will be configured as apparent to those skilled in the art that modifications and variations could be made without departing from the scope of the present disclosure as defined by the appended claims.

What is claimed is:

1. A semiconductor device, comprising:
a first semiconductor structure including a substrate, a plurality of circuit devices on the substrate, and a plurality of circuit interconnection lines on the plurality of circuit devices; and
a second semiconductor structure on the first semiconductor structure,
wherein the second semiconductor structure includes:
a plate layer;
a plurality of gate electrodes on the plate layer and spaced apart from each other in a first direction perpendicular to an upper surface of the plate layer, wherein the plurality of gate electrodes extend by different lengths in a second direction perpendicular to the first direction, and wherein the plurality of gate electrodes form a plurality of staircase regions;
a gap-fill insulating layer filling a region between the plurality of gate electrodes spaced apart from each other in the second direction in the plurality of staircase regions;
a plurality of channel structures extending through at least a portion of the plurality of gate electrodes, wherein the plurality of channel structures extend in the first direction; and
a plurality of contact plugs extending through the gap-fill insulating layer and the gate electrodes in the staircase regions, wherein the plurality of contact plugs extend in the first direction,
wherein the gap-fill insulating layer extends along a plurality of side surfaces of the plurality of gate electrodes and a plurality of side surfaces of the plurality of contact plugs, and
wherein the gap-fill insulating layer includes a plurality of voids spaced apart from the plurality of contact plugs and the plurality of gate electrodes.

2. The semiconductor device of claim 1, wherein the plurality of voids are disposed between the plurality of contact plugs, and wherein the plurality of voids are further disposed between the plurality of contact plugs and a stack structure of the plurality of gate electrodes.

3. The semiconductor device of claim 1, wherein at least one void of the plurality of voids includes a region having a shape corresponding to a shape of the plurality of staircase regions.

4. The semiconductor device of claim 1, wherein the plurality of voids have a symmetrical shape in a third direction perpendicular to the first direction and the second direction on opposing sides of at least one contact plug of the plurality of contact plugs.

5. The semiconductor device of claim 1, wherein the gap-fill insulating layer surrounds the plurality of voids, and wherein the gap-fill insulating layer has a substantially constant thickness.

6. The semiconductor device of claim 1, wherein the second semiconductor structure further includes:
a plurality of interlayer insulating layers alternately stacked with the plurality of gate electrodes, wherein the plurality of interlayer insulating layers form a stack structure; and
a first cell insulating layer covering the plurality of side surfaces of the plurality of gate electrodes and a plurality of side surfaces of the plurality of interlayer insulating layers, wherein the first cell insulating layer is in contact with the gap-fill insulating layer in the plurality of staircase regions.

7. The semiconductor device of claim 1, wherein the second semiconductor structure further includes a plurality of second cell insulating layers covering a portion of the plurality of side surfaces of the contact plugs.

8. The semiconductor device of claim 7, wherein the plurality of second cell insulating layers include a plurality of internal side surfaces in contact with the plurality of contact plugs, and include a plurality of external side surfaces in contact with the gap-fill insulating layer.

9. The semiconductor device of claim 1,
wherein the second semiconductor structure further includes a third cell insulating layer on a portion of the gap-fill insulating layer and a stack structure of the plurality of gate electrodes, and
wherein the third cell insulating layer has a plurality of openings filled with the gap-fill insulating layer.

10. The semiconductor device of claim 1,
wherein each staircase region of the staircase regions includes a first step structure and a second step structure,
wherein a level of the first step structure decreases in the second direction,
wherein a level of the second step structure increases in the second direction, and
wherein the plurality of contact plugs extend through at least the first step structure.

11. The semiconductor device of claim 1,
wherein the plurality of gate electrodes form a first stack structure and a second stack structure,
wherein the first stack structure and the second stack structure each form a staircase region,
wherein the first stack structure and the second stack structure are stacked in the first direction, and
wherein the gap-fill insulating layer includes a first gap-fill insulating layer on the staircase region of the first stack structure and a second gap-fill insulating layer on the staircase region of the second stack structure.

12. The semiconductor device of claim 1,
wherein the second semiconductor structure further includes a plurality of isolation regions extending through at least a portion of the plurality of gate electrodes and extending in the second direction, and
wherein a stack structure of the plurality of gate electrodes includes a plurality of wall regions between the plurality of isolation regions and the plurality of staircase regions in a third direction perpendicular to the first direction and the second direction.

13. A semiconductor device, comprising:
a plate layer;
a plurality of conductive layers on the plate layer and spaced apart from each other in a first direction perpendicular to an upper surface of the plate layer, wherein the plurality of conductive layers extend by different lengths in a second direction perpendicular to the first direction, and wherein the plurality of conductive layers form a staircase region;
a gap-fill insulating layer on the staircase region; and
a plurality of vertical structures extending through the gap-fill insulating layer and the plurality of conductive layers in the staircase region, wherein the plurality of vertical structures extend in the first direction, and
wherein the gap-fill insulating layer includes a plurality of voids disposed in a third direction perpendicular to the first direction and the second direction, and
wherein the plurality of voids are disposed symmetrically with respect to at least one of at least one vertical structure of the plurality of vertical structures, or a center of the staircase region.

14. The semiconductor device of claim 13,
wherein the gap-fill insulating layer extends along a plurality of side surfaces of the plurality of vertical structures, and
wherein the plurality of voids are spaced apart from the plurality of vertical structures.

15. The semiconductor device of claim 13,
wherein the gap-fill insulating layer extends along the staircase region, and
wherein the plurality of voids are spaced apart from the plurality of conductive layers.

16. The semiconductor device of claim 13, wherein the plurality of voids are disposed between the plurality of vertical structures, and wherein the plurality of voids are further disposed between a stack structure of the plurality of conductive layers and the plurality of vertical structures.

17. The semiconductor device of claim 13, further comprising:
a plurality of oxide layers interposed between the gap-fill insulating layer and the plurality of vertical structures.

18. The semiconductor device of claim 13,
wherein a plurality of upper ends of the vertical structures are on a first level, and
wherein a portion of an upper surface of the gap-fill insulating layer is on a second level lower than the first level.

19. A data storage system, comprising:
a semiconductor storage device including
a first semiconductor structure including a plurality of circuit devices,
a second semiconductor structure on a surface of the first semiconductor structure, and
an input/output pad electrically connected to the plurality of circuit devices; and
a controller electrically connected to the semiconductor storage device through the input/output pad, wherein the controller is configured to control the semiconductor storage device,
wherein the second semiconductor structure includes:
a plate layer;
a plurality of gate electrodes on the plate layer and spaced apart from each other in a first direction perpendicular to an upper surface of the plate layer, wherein the plurality of gate electrodes extend by different lengths in a second direction perpendicular to the first direction, and wherein the plurality of gate electrodes form a staircase region;
a gap-fill insulating layer on the staircase region; and
a plurality of contact plugs extending through the gap-fill insulating layer and the staircase region, wherein the plurality of contact plugs extend in the first direction, and
wherein the gap-fill insulating layer includes a plurality of voids spaced apart from the plurality of contact plugs and the plurality of gate electrodes.

20. The semiconductor device of claim 19, wherein the plurality of voids are disposed symmetrically around the plurality of contact plugs in a third direction perpendicular to the first direction and the second direction.

21. A method of manufacturing a semiconductor device, the method comprising:
forming a mold structure by alternately stacking a plurality of sacrificial insulating layers and a plurality of interlayer insulating layers on a plate layer;
forming a staircase region having a step structure by partially removing the mold structure;
forming a gap-fill sacrificial layer filling the staircase region;
forming a plurality of vertical sacrificial layers extending through the gap-fill sacrificial layer and the mold structure;
removing the gap-fill sacrificial layer; and
forming a gap-fill insulating layer including a plurality of voids in a region from which the gap-fill sacrificial layer is removed.

22. The method of claim 21, further comprising:
forming a cell insulating layer on the gap-fill sacrificial layer and the mold structure; and
forming a plurality of openings by partially removing the cell insulating layer to expose at least a portion of an upper surface of the gap-fill sacrificial layer.

23. The method of claim 21, wherein forming the plurality of vertical sacrificial layers includes:
forming a plurality of vertical holes extending through the gap-fill sacrificial layer and the mold structure;
forming a plurality of oxide layers by oxidizing the gap-fill sacrificial layer exposed through the plurality of vertical holes; and
filling the plurality of vertical holes with a material forming the plurality of vertical sacrificial layers.

24. The method of claim 21, wherein the gap-fill insulating layer is formed conformally along a plurality of exposed side surfaces of the plurality of vertical sacrificial layers and the staircase region.

25. The method of claim 21, further comprising:
removing the plurality of vertical sacrificial layers; and
forming a plurality of contact plugs in a region from which the plurality of vertical sacrificial layers are removed.
